(19) United States
(12) Patent Application Publication
(10) Pub. No.: US 2006/0185594 A1
(43) Pub. Date: Aug. 24, 2006

(54) Plasma treating apparatus and its electrode structure

(76) Inventors: Tsuyoshi Uehara, Kyoto (JP); Takayuki Ono, Ibaraki (JP); Hitoshi Sezukuri, Kyoto (JP); Hiroto Takeuchi, Ibaraki (JP); Hiromi Komiya, Kyoto (JP); Takumi Ito, Kyoto (JP); Takae Ohta, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/565,004

(22) PCT Filed: Jul. 22, 2004
(86) PCT No.: PCT/JP04/10415

§ 371 Date: Jan. 19, 2006

(30) Foreign Application Priority Data
Jul. 23, 2003 (JP) 2003-278536
Jul. 23, 2003 (JP) 2003-278537
Sep. 30, 2003 (JP) 2003-342195
Nov. 14, 2003 (JP) 2003-385691
Mar. 19, 2004 (JP) 2004-080166
Mar. 19, 2004 (JP) 2004-080167
Jul. 22, 2004 (JP) 2004-214182
Jul. 22, 2004 (JP) 2004-214183

(51) Int. Cl. C23C 16/00

(52) U.S. Cl. 118/723 E; 118/718

(57) ABSTRACT

[PROBLEM TO BE SOLVED]To reduce the bending amount caused by Coulomb force of electrodes and obtain uniformity of surface processing in a plasma processing apparatus for a workpiece having a large area. [SOLUTION MEANS]

An electrode structure 30X of a plasma processing apparatus comprises a pair of electrode rows 31X, 32X extending leftward and rightward and opposite to each other in back and forth directions. Each electrode row includes a plurality of electrode members 31A through 32C bilaterally arranged in a side-by-side relation. The electrode members of the two electrode rows, which are bilaterally arranged in substantially same positions, have opposite polarities and form row-to-row partial gaps 33p therebetween. The electrode members arranged adjacent to each other are opposite in polarity with respect to each other.

### TECHNICAL FIELD

This invention relates to a plasma processing apparatus for plasmatizing a processing gas between electrodes and processing the surface of a workpiece to be processed.

### BACKGROUND ART

For example, in Patent Document 1, there is described a so-called remote type plasma processing apparatus in which a processing gas is plasmatized in a discharging space between electrodes and jetted so as to be contacted to a workpiece fed by a carrier means. The electrodes of the apparatus are of a structure wherein two flat electrode plates are opposingly arranged in parallel relation. Normally, those electrode plates have a length equal to or longer than the width (in the direction orthogonal to the feeding direction) of the workpiece. Therefore, the discharging space between those electrode plates and the plasma jet port connected to the discharging space also have a length equal to or longer than the width dimension of the workpiece. Owing to this arrangement, the entire width of the workpiece can be plasma processed at a time by uniformly jetting the processing gas, which has been plasmatized between the electrodes, through the jet port over an entire length area thereof. Consequently, the processing efficiency can be improved.

In Patent Document 2, there is described an apparatus for conducting a plasma surface processing by converting a direct current to a continuous wave by inverter and applying it between a pair of electrodes.

[Patent Document 1]

Japanese Patent Application Laid-Open No. 2002-143795 (page 1, FIG. 4)

Japanese Patent Application Laid-Open No. 2003-203800 (page 1)

### DISCLOSURE OF THE INVENTION

[Problem to be Solved by the Invention]

Recently, upsizing of the workpiece such as a liquid crystal glass substrate has been and still being progressed. Among them, even those having one side so large as, for example, 1.5 mm to several mm appeared. In order to cope with a workpiece having such a wide width and a large surface area, the electrode plates of the plasma processing apparatus are required to be made long.

However, the more the length of the electrode plates is increased, the more the difficulty is increased for obtaining the dimensional accuracy. In addition, the electrode plates become readily bendable due to the Coulomb force acting between the adjacent electrode plates, thermal stress caused by difference in thermal expansion coefficient between a metal main body constituting the electrodes and a solid dielectric of the surface thereof and difference in temperature within the electrodes, and the like. Consequently, the thickness of the discharging space tends to be non-uniform and thus, uniformity of the surface processing tends to be impaired. In order to cope with the Coulomb force, it is possible that the electrode plates are increased in thickness so as to increase the rigidity. If an arrangement is made in that way, however, the electrodes are increased in weight and the electrode support construction for supporting the same is not only subjected to heavy load but also the material cost and processing costs are increased.

Moreover, if the electrodes are upsized, power supplied from the power source is reduced per unit area and processing performance is lowered. This problem can be solved only if the power source is replaced with one having a large capacity. However, this is practically not easy in view of production cost, etc. Another attempt is to employ a plurality of power sources each having a small capacity and connect them to a single electrode plate in order to increase the total supply of power. In that case, however, those power sources are required to be synchronized with one another.

[Means for Solving the Problem]

The first feature of the present invention relates to an apparatus for conducting a plasma processing by plasmatizing a processing gas in a discharging space and blown it off so as to be contacted to a workpiece to be processed, and more particularly to an electrode structure for forming such a discharging space as just mentioned above. This electrode structure includes a first electrode row composed of a plurality of electrode members arranged in a side-by-side relation in one direction and a second electrode row composed of another plurality of electrode members.

One of the electrode members of the first electrode row and one of the electrode members of the second electrode rows, which are arranged in the substantially same position in the side-by-side arranging directions, have opposite polarities, and a row-to-row partial gap serving as a part of the discharging space is constituted therebetween.

A row-to-row gap including the row-to-row partial gap is formed between the first and second electrode rows. That is, a row-to-row gap consisting of a plurality of the row-to-row partial gaps connected in a row is formed between the first and second electrode rows.

The lengths of the electrode members of the first and second electrode rows are each desirously shorter than that of the workpiece.

The lengths of the first and second electrode rows each desirously correspond to that of the workpiece as a whole.

The row-to-row gap is constituted by arranging a plurality of the row-to-row partial gaps in a side-by-side relation in a row and constitutes generally the whole or most part of the discharge space.

Owing to the above-mentioned arrangement, the workpiece can be processed generally over the entire width, a favorable processing efficiency can be obtained and the length of each electrode member can be reduced to about a fraction of the width of the workpiece. In the alternative, the individual electrode members are reduced in length without depending on the width dimension of the workpiece and the length of the electrode row can be made correspondent to the width of the workpiece by adjusting the side-by-side arranging number of the electrode members. Owing to this arrangement, the dimensional accuracy can easily be obtained, in addition, the bending amount caused by Coulomb force, etc. can be reduced and thus, uniformity of the surface processing can be obtained. There is no need of enlarging the thickness of the electrode members and weight increase can be avoided, thereby reducing a load onto the support structure, and material cost, etc. can be prevented from increasing.

The workpiece is preferably relatively moved in such a manner as to intersect with the extending direction (aide-by-side arranging directions of the electrode members of the first and second electrode rows) of the first and second electrode rows. That is, the plasma processing apparatus desirously comprises a discharge processor including the electrode structure and a moving means for relatively moving the workpiece in a direction intersecting with the row-to-row gap of the electrode structure with respect to the discharge processor.

The polarities include an electric field applying pole and a grounding pole. The electrode members constituting the electric field applying pole are desirously connected to different power sources, respectively (see FIG. 2). Owing to this arrangement, the supply power per unit area of each electrode member can be sufficiently increased without using a power source having a large capacity, the processing gas can be sufficiently plasmatized and the processing performance can be enhanced. Moreover, since power supply is made separately to each electrode member per each power source, the power sources are not required to be synchronized with each other.

The electrode members constituting the electric field applying pole may be connected to a common (single) power source (see FIG. 39).

The row-to-row partial gaps adjacent to each other may be communicated with each other, either directly or through a communication space (see FIGS. 2 and 42) or they may be partitioned by a partition wall.

At least one of the electrode members which are faced with each other at the substantially same position of the first and second electrode rows is provided at the mating surface with a solid dielectric. The solid dielectric may be composed of a thermal spraying film such as alumina, or it may be composed of a plate such as ceramic and this plate may be applied to the surface of the electrode member. It is also accepted that the electrode member is received in a container composed of ceramic or the like and this container is functioned as a solid dielectric layer.

The electrode members of the first electrode row and the electrode members of the second electrode row may be deviated in the side-by-side arranging direction (see FIG. 33). In this case, the electrode members which are opposite to each other over more than a half of their lengths correspond to those which are arranged in an opposing relation “substantially in the same position in the side-by-side arranging direction”.

The intervals between the adjacent electrode members in each electrode row are properly established in accordance with processing conditions, etc.

It is desirous that the electrode members, which are adjacent to each other in the side-by-side arranging directions, are opposite (reversed) in polarities, and it is more desirous that an in-row gap is formed between two of the electrode members adjacent in the side-by-side arranging directions in the first electrode row/second electrode row (see FIG. 2). Owing to this arrangement, this in-row gap can also serve as another part of the discharge space and even the part of the workpiece corresponding to the boundary between the adjacent electrode members can also be reliably surface processed. Thus, uniformity of processing can be more enhanced. In case the in-row gap is formed between the electrode members, which are adjacent in the side-by-side arranging directions, as another part of the discharge space, those adjacent electrode members are provided, at least at one end face thereof, with the solid dielectric. Moreover, in case the electrode members constituting the electric field applying pole are connected to different power sources, respectively, the supply power per unit area can sufficiently be increased and the processing performance can be enhanced. In addition, there is no fear that an electric arc is not generated even if the power sources are not synchronized with each other because the electric field applying poles are not directly adjacent to each other.

Moreover, it is desirous that one of the two electrode members arranged adjacent to each other in the side-by-side arranging directions in the first electrode row and/or second electrode row includes a first surface forming the row-to-row gap and a second surface disposed at an angle with respect to the first surface, and the other of the two electrode members includes a third surface generally flush with the first surface and forming the row-to-row gap and a fourth surface placed opposite to the second surface and arranged at an angle with respect to the third surface, and the in-row gap is formed between the second surface and the fourth surface.

It is also accepted that the first surface and the second surface are disposed at a right angle, the third surface and the fourth surface are disposed at a right angle and the in-row gap is disposed orthogonal to the row-to-row gap.

It is also accepted that the first surface and the second surface are disposed at an abuse angle, the third surface and the fourth surface are disposed at an acute angle and the in-row gap is disposed slantwise with respect to the row-to-row gap (see FIG. 34). Owing to this arrangement, a favorable discharge is readily occurred even at the corner parts on the obtuse angle side formed between the first surface and the second surface, and processing omission can be prevented from occurring.

In the above arrangement, it is desirous that the corner on the side of the obtuse angle formed between the first surface and second surface is R-chamfered with a relatively large radius of curvature, while the corner on the side of the acute angle formed between the third surface and fourth surface is R-chamfered with a relatively small radius of curvature (see FIG. 36). Owing to this arrangement, the corner on the obtuse angle side formed between the first surface and the second surface can be made smoother and the corner on the acute angle side formed between the third surface and the fourth surface are protruded to greater possible extent so that a space formed between those two corners and the other electrode row can be reduced and thus, a favorable discharge can be occurred easily and reliably at the corner part on the obtuse angle side.

It is also accepted that in the electrode row on the opposite side of the electrode row having the first surface, the electrode member located in the substantially same position as the electrode member having the first surface is arranged astride the first surface and the end face of the third surface (see FIG. 34). Owing to this arrangement, discharge can more easily be occurred at the corner part on the obtuse angle side formed between the first surface and the second surface and processing omission can be prevented from occurring more reliably.

It is also accepted that two in-row gaps are formed among three electrode members which are adjacent to each other in the side-by-side arranging directions in the first electrode row and/or second electrode row, and those two in-row gaps are inclined in the mutually opposite directions (see FIG. 37).

All electrode members only excluding those which are arranged on the opposite ends of the electrode row may have a trapezoidal configuration whose opposite end faces are symmetrically inclined in the mutually opposite directions, a parallelepiped configuration or any other square configuration.

It is desirous that the downstream end of the in-row gap is open in such a manner as to be able to jet a processing gas therefrom and without passing the processing gas through the row-to-row gap (see FIGS. 27 and 35). Owing to this arrangement, the processing gas plasmatized in the in-row gap can be jetted directly through the in-row gap and applied onto the workpiece.

Instead of the staggered polarity arrangement structure (FIG. 2 and elsewhere), the electrode members adjacent in the side-by-side arranging directions may have the same polarity (see FIG. 40).

In the above-mentioned arrangement, the electrode members constituting the electric field applying pole of all the poles (electric field applying pole and grounding pole) may be connected to different power sources, respectively (see FIG. 40). Owing to this arrangement, the supply power per unit area can sufficiently be increased and the processing performance can be enhanced.

Moreover, an insulating partition wall is desirously interposed between the electrode members having the electric field applying pole adjacent in the side-by-side arranging directions (see FIG. 40). Owing to this arrangement, an electric arc can be prevented from occurring between the adjacent electrode members even if the power sources are not synchronized with each other. It is also accepted that an insulating partition wall is also interposed between the electrode members having the grounding pole.

It is desirous that the discharge space is provided at an upstream end thereof with an introduction port forming part for forming a processing gas introduction port and at a downstream side thereof with a jet port forming part for forming a jet port. By doing so, the extending direction i.e., the side-by-side arranging direction of the first and second electric rows intersects with a direction toward the jet port from the processing gas introduction port. One of the electrode members of the first electrode row and one of the electrode members of the second electrode rows, which are arranged at a first position in the side-by-side arranging directions, have opposite polarities and form a first row-to-row partial gap therebetween, the first row-to-row partial gap serving as a part of the discharge space, and another of the electrode members of the first electrode row and another of the electrode members of the second electrode rows, which are arranged at a second position adjacent to the first position have opposite polarities with each other and form a second row-to-row partial gap therebetween, the second row-to-row partial gap serving as another part of the discharge space.

Moreover, it is desirous that the apparatus further comprises a gas guide which guides a processing gas flow passing through a part near the second position (part near the adjacent gap) in the first row-to-row partial gap to a boundary between the first position and the second position or in a direction toward the second position (direction toward the adjacent gap) (see FIGS. 5 through 30). It is more desirous that the apparatus is provided with a gas guide which guides the processing gas flow passing not only through the first row-to-row partial gap but also through the side part near the adjacent row-to-row gap part in each row-to-row partial gap to the adjacent side.

Owing to the above-mentioned arrangement, a plasma can sufficiently be sprayed onto a place of the workpiece corresponding to the boundary between the adjacent row-to-row partial gaps and processing omission can be prevented from occurring. Thus, accompanying with the bending reducing effect, uniformity of surface processing can sufficiently be obtained.

In the above-mentioned case, if the electrode members having the electric field applying pole are connected with different power sources, respectively, the supply power per unit area can sufficiently be obtained without increasing each power source capacity and in addition, those power sources are not required to be synchronized with each other.

The first row-to-row gap part may be provided at the inside of a part near the second position with a gas guiding member having a gas guiding surface, as said gas guide, which is inclined in the second position direction toward the jet port (see FIG. 5). Owing to this arrangement, the gas flow near the adjacent gap can reliably be introduced to the adjacent direction along the gas guiding surface. In that case, it is desirous that the gas guiding member is provided at the jet port side from the gas guiding surface with a gas return surface which is inclined in the opposite direction to the gas guiding surface (see FIG. 6). Owing to this arrangement, a part of the processing gas flowing toward the adjacent direction can be flown around toward the jet port side from the gas guiding member, the processing gas can also be sprayed onto a place corresponding to the gas guiding member in the workplace and processing omission can reliably be prevented from occurring.

The gas guide may also be disposed at the introduction port forming part (the processing gas induction side from the electrode structure).

For example, it is also accepted that the introduction port includes a branch port leading to a part near the second position of the first row-to-row partial gap and this branch port is bent toward the second position thereby constituting the gas guide (see FIG. 9). Owing to this arrangement, the processing gas can reliably be introduced to the boundary between the row-to-row partial gaps.

A flow rectification plate, as the gas guide, slanted toward the second position may be received in the introduction port at a position corresponding to the part near the second position of the first row-to-row partial gap (see FIG. 13). Owing to this arrangement, the processing gas can reliably be introduced to the boundary between the row-to-row partial gaps.

The gas guide may include a blocking part for blocking an end part on the introduction port side located at the boundary between the first row-to-row partial gap and the second row-to-row partial gap and opening the area on the jet port side therefrom (see FIG. 15). Owing to this arrangement, the processing gas can flow to the boundary between the row-to-row partial gaps after being plasmatized in the row-to-row partial gap.

It is also accepted that the introduction port of the introduction port forming part having a slit-like configuration extending in the side-by-side arranging directions and disposed astride the first row-to-row part gas and the second row-to-row partial gap, and the blocking part is received in the introduction port at a position corresponding to the boundary between the first row-to-row partial gap and the second row-to-row partial gap (see FIG. 15).

It is also accepted that the electrode structure comprises a spacer having a pair of interposing parts and a connection part for connecting the interposing parts, one of the interposing parts being sandwiched between the electrode member located at the first position and the electrode member located at the second position in the first electrode row, the other of the interposing parts being sandwiched between the electrode member located at the first position and the electrode member located at the second position in the second electrode row and the connection part is arranged close to the end part on the introduction port side of the boundary, thereby being provided as the blocking part (see FIG. 18). The processing gas is flowed to the part on the jet port side from the connection part of the boundary via the row-to-row partial gaps.

It is also accepted that the gas guide is disposed at the jet port forming part (on the jet port side from the electrode structure) and introducing a processing gas coming from a part near the second position of the first row-to-row partial gap toward the second position (see FIG. 21).

In the above-mentioned arrangement, it is also accepted that the gas guide includes a gas guiding surface inclined in a second direction and arranged at a position corresponding to the part near the second position of the first row-to-row partial gap in the jet port of the jet port forming part (see FIG. 21). Owing to this arrangement, the plasmatized processing gas can reliably be applied to the part in the workpiece corresponding to the boundary between the row-to-row partial gaps.

It is also accepted that the gas guide is arranged at a position corresponding to the boundary between the first row-to-row partial gap and the second row-to-row partial gap in the jet port of the jet port forming part in such a manner as to be close to the electrode structure side, and the gas guide includes a blocking part for blocking the end part on the jet port side of the boundary (see FIG. 26). Owing to this arrangement, the processing gas flowing through the boundary between the row-to-row partial gaps can be flown to the row-to-row partial gap and plasmatized therein, and the processing gas plasmatized in the row-to-row partial gap can be flown around into the jet port on the downstream side of the blocking part.

It is also accepted that the jet port having a slit-like configuration is connected to the first and second row-to-row partial gaps in such a manner as to astride the first row-to-row partial gap and the second row-to-row partial gap, and the processing gas coming from the first row-to-row partial gap is allowed to disperse thereby to constitute the gas guide (see FIG. 27).

It is also accepted that the jet port forming part includes a porous plate, a processing gas coming from the first row-to-row partial gap is dispersed and thus, diffused also toward the second position and jetted out, thereby providing the porous plate as the gas guide (see FIG. 23). Owing to this arrangement, the processing gas can be jetted out reliably and uniformly, and processing omission can reliably be prevented from occurring.

It is also accepted that a part of the jet port of the jet port forming part corresponding to the boundary between the first row-to-row partial gap and the second row-to-row partial gap is larger in opening width than another part of the jet port of the jet port forming part corresponding to the first row-to-row partial gap, and the former part having the large opening width is provided as the gas guide (see FIG. 27). Owing to this arrangement, the flow resistance at the part corresponding to the boundary between the first and second row-to-row partial gaps in the jet port can be made smaller than the flow resistance at the part corresponding to the first row-to-row partial gap, and the processing gas plasmatized in the first row-to-row partial gap can be flow to the part corresponding to the boundary.

It is also accepted that the electrode member located at the first position and the electrode member located at the second position in the first electrode row have opposite polarities with respect to each other and an in-row gap is formed between those electrode members, and

the introduction port of the introduction port forming part includes a row-to-row introduction port disposed astride the first row-to-row partial gap and the second row-to-row partial gap and an in-row introduction port directly connected to the in-row gap (see FIG. 32).

A second feature of the present invention resides in a plasma processing apparatus comprising an electric field applying electrode and a grounding electrode placed opposite to each other and forming a processing gas path therebetween, and a plurality of power source devices for applying an electric field for plasmatizing the processing gas between those electrodes, and a synchronizer for synchronizing those power source devices (see FIG. 44).

Owing to the above-mentioned arrangement, the supply power per unit area of the electrode can be sufficiently increased even if the capacity of each power source device is small, processing performance can be obtained. In addition, deviation in phase between the power source devices can be eliminated and thus, a favorable plasma surface processing can be conducted.

It is desirous that the plurality of power source devices each include a rectifier for rectifying a commercial-use AC voltage to a DC voltage, and an inverter for switching the DC voltage after rectification to an AC voltage by a switching element, and the synchronizer controls the inverters for the power source devices such that the inverters are synchronized in switching action with each other (see FIGS. 45 through 48). Owing to this arrangement, the plurality of power sources can reliably be synchronized. The output from the inverter may be a sine wave AC, a pulse wave AC, a rectangular wave AC or the like.

It is also accepted that the synchronizer includes a common gate signal output part for the inverters of the power source devices, a gate signal outputted from the gate signal output part being inputted in a gate of the switching element of each of the inverters in parallel (FIG. 45). In the alternative, it is also accepted that the synchronizer includes a plurality of gate signal output parts which are provided to the inverter of each power source device and a common synchronization signal supply part for the gate signal output parts, a synchronization signal outputted from the synchronization signal supply part being inputted into each of the gate signal output parts in parallel so that in response to input of the synchronization signal, the gate signal output parts each input a gate signal into the gate of the switching element of the corresponding inverter (see FIGS. 46 and 47).

It is also accepted that of the electric field applying electrode and grounding electrode, at least the electric field applying electrode is divided into a plurality of electrode members and each electric member is connected with a power source device.

That is, the apparatus may comprise an electric field applying electrode including a first and a second divided electrode member;

a grounding electrode for forming a processing gas path between the first and second electric field applying electrodes;

a first power source device for applying an electric field for plasmatizing the processing gas between the first divided electrode member and the grounding electrode;

a second power source device for applying an electric field for plasmatizing the processing gas between the second divided electrode member and the grounding electrode; and

a synchronizer for synchronizing the first and second power source devices (see FIG. 44).

Owing to the above-mentioned arrangement, each divided electrode member can be reduced in size and bending caused by dead weight, Coulomb force occurrable between the opposing electrodes, or etc. can be reduced as much as possible.

It is desirous that the first power source device includes a first rectifier for rectifying a commercial-use AC voltage to a DC voltage, and a first inverter for switching the DC voltage after rectification to an AC voltage, and the synchronizer controls the inverters for the power source devices such that the inverters are synchronized in switching action with each other (see FIGS. 45 through 48).

It is also accepted that the plurality of divided electrode members are arranged in a side-by-side relation in a row, and the grounding electrode is disposed in parallel with this row (see FIG. 44). Also in this arrangement, electric potential difference can be prevented from occurring between the divided electrode members by the synchronizer, and an electric arc can be prevented from occurring between those divided electrode members. By virtue of this feature, the interval between the divided electrode members can be reduced. The interval can also be eliminated so that the divided electrode members are abutted with each other. Thus, processing irregularity can be prevented from occurring at the part in workpiece corresponding to the interval between the divided electrode members and a favorable plasma surface processing can reliably be conducted. The grounding electrode employed in the above-mentioned arrangement may be an integral one or it may be divided into grounding divided electrode members. The electric field applying divided electrode members and the grounding divided electrode members, which are arranged in the same position in the side-by-side arranging directions, may be correctly faced with each other or may be deviated in the side-by-side arranging directions.

It is also accepted that the electric field applying electrode is not divided into a plurality of electrode members but it is an integral one and this single electric field applying electrode is connected with a plurality of power source devices. Even in that case, the electric field can be prevented from becoming instable because the plurality of power source devices are synchronized.

It is also accepted that the synchronizer includes a common gate signal output part for the first and second inverters, and a gate signal outputted from the gate signal output part is inputted in gates of the switching elements of the first and second inverters in parallel (see FIG. 45). It is also accepted that the synchronizer includes a first and a second gate signal output part and a common synchronization signal supply part for the first and second gate signal output parts, synchronization signals outputted from the synchronization signal supply part are inputted into the first and second gate signal output parts in parallel so that in response to inputs of the synchronization signals, the first and second gate signal output parts input a gate signal into the gates of the switching elements of the first and second inverters, respectively (see FIGS. 6 and 47).

It is also accepted that the first power source device is a resonance type high frequency power source which is actuated at a resonance frequency of a first LC resonance circuit constituted by the first divided electrode member and the secondary coil of an output transformer of the first power source device, and the second power source device is a resonance type high frequency power source which is actuated at a resonance frequency of a second LC resonance circuit constituted by the second divided electrode member and the secondary coil of an output transformer of the second power source device. In that case, it is also accepted that the synchronizer detects an output waveform (primary current waveform of the output transformer of the first power source device) of the first inverter, corrects the oscillation frequency based on the detected signal, and outputs synchronization signals based on the oscillation frequency after correction to the first and second gate signal detectors in parallel from the common synchronization signal supplying part and in response thereto, the first gate signal output part inputs a gate signal into the gate of the switching element of the first inverter and the second gate signal output part inputs a gate signal into the gate of the switching element of the second inverter (see FIG. 48).

It is also accepted that in case electrostatic capacity between the first divided electrode member and the grounding electrode is larger than that between the second divided electrode member and the grounding electrode, the second electrode device is longer in rising/falling time of applied voltage than the first power source device (see FIG. 49) or the second divided electrode members are connected with a condenser in parallel (see FIG. 50). Owing to this arrangement, the voltage waveforms applied to the first and second divided electrode members can be made coincident with each other.

Plasma processing of the present invention is preferably conducted under pressure of the neighborhood of atmospheric pressure (normal pressure). The neighborhood of atmospheric pressure refers to pressure in the range of 1.013×10⁴ through 50.663×10⁴ Pa, preferably in the range of 1.333×10⁴ through 10.664×10⁴ Pa (100 through 800 Torr) and more preferably in the range of 9.331 10⁴ through 10.397×10⁴ Pa (700 through 780 Torr) when easiness of pressure adjustment and simplification of structure of the apparatus are taken into account.

The present invention preferably conducts processing by generating plasma by causing an atmospheric glow discharge, i.e., a glow discharge to occur under pressure in the neighborhood of atmospheric pressure.

[Best Mode for Carrying Out the Invention]

Embodiments of the present invention will be described hereinafter with reference to the drawings.

FIGS. 1 through 3 show a remote type normal pressure plasma processing apparatus according to the first embodiment. A workpiece W of this apparatus is, for example, a large sized liquid crystal glass substrate, and its widthwise (left and right directions in FIGS. 2 and 3, and a direction orthogonal to the paper surface in FIG. 1) dimension is about 1.5 m. The workpiece W may be heated, cooled or held in a normal temperature.

As shown in FIG. 1, the plasma processing apparatus comprises a nozzle head 1, a processing gas source 2, three (plural) power sources 3A, 3B, 3C, and a conveying means 4.

The nozzle head 1 is supported by a support means, not shown, such that the blowing direction is directed downward.

Processing gases suited to the purpose of processing are reserved in the processing gas source 2.

The power sources 3A, 3B, 3C output the same pulse-like voltage. It is desirous that the rising/falling time of this pulse is 10 μs or less and the electric field intensity is 10 to 1000 kV/cm and the frequency is 0.5 kHz or more in a gap 33p of a row-to-row part as later described.

Instead of pulse wave, a power source of continuous wave such as high frequency may be used.

The conveying means 4 is composed of, for example, a roller conveyor and conveys a glass substrate W as the workpiece in the back and forth directions (left and right directions in FIG. 1) and passes it underside the nozzle head 1. The processing gas plasmatized in the nozzle head 1 is blown onto this glass substrate W and plasma processing is conducted generally under normal pressure. Of course, it is also accepted that the glass substrate W is fixed and the nozzle head 1 is moved. The conveying means 4 may be composed of a belt conveyor. In the alternative, the workpiece may be conveyed by being sandwiched between upper and lower rollers.

The nozzle head 1 according to the remote type normal pressure plasma processing apparatus will be described in detail. As shown in FIGS. 1 and 2, the nozzle head 1 comprises an upper processing gas introduction part 20 and a lower discharge processor 30. The nozzle head 1 is extended long in the bilateral direction orthogonal to the conveying directions (up and down directions in FIGS. 2 and 3) of the glass substrate W.

The processing gas introduction part 20 includes a pipe unit 25 composed of two pipes 21, 22 extending leftward and rightward (directions orthogonal to the paper surface in FIG. 1), and bilaterally elongate chambers 23, 24 arranged in an up and down relation. A large number of spot-like holes 25a passing from the upper sides of the respective pipes 21, 22 to the upper chamber 23 are arranged at short intervals along the longitudinal direction. A processing gas source 2 is connected to the left end (near side of the paper surface in FIG. 1) of the pipe 21 and the right end (inner side of the paper surface in FIG. 1) of the other pipe 22 through a gas supply path 2a. The processing gas coming from the processing gas source 2 are flown into the upper chamber 23 through those spot-like holes 25a while flowing in the reverse directions within the pipes 21, 22. Thereafter, the processing gas is flown into the lower chamber 24 via slit-like gaps 20a formed in front and rear sides of the pipe unit 25. Owing to this arrangement, the processing gas is uniformized at all positions in the bilaterally longitudinal directions of the processing gas introduction part 20 and introduced into the discharge processor 30.

The discharge processor 30 comprises a frame 40, an electrode holder 48 received in this frame 40, an electrode unit (electrode structure) 30×disposed within the holder 48 and a lower plate 49. The frame 40 includes an upper plate 41 and side plates 42 which are each formed of a rigid metal. The holder 48 includes a pair of inverted L-shaped members in section which are each formed of an insulating material such as ceramic and resin.

A slit-like through-hole 41a connecting to the chamber 24 and extending leftward and rightward (direction orthogonal to the paper surface in FIG. 1) is formed in the upper plate 41 of the frame 40. A slit-like gap 48a connected to the through-hole 41a and extending leftward and rightward is formed between upper side parts of the pair of inverted L-shaped members in section of the holder 48. A slit-like processing gas introduction port 43a extending leftward and rightward is constituted by the through-hole 41a and the gap 48a. An introduction port forming part 43 is constituted by the upper plate of the frame 40 and upper side parts of the pair of inverted L-shaped members in section.

The lower plate 49 formed of an insulating member includes a slit-like jet port 49a extending leftward and rightward and constitutes a jet port forming part.

The introduction port forming part 43 including the processing gas introduction port 43a and the lower plate 49 including the jet port 49a are arranged in such a manner as to vertically sandwich the electrode unit 30X.

The electrode unit 30X will be described in detail, next. As shown in FIGS. 1 and 2, the electrode unit 30X includes a pair of electrode rows 31X, 32X which are arranged in opposing relation in the back and forth directions. The electrode rows 31X, 32X are each extended leftward and rightward. The front-side first electrode row 31X is comprised of three (n pieces) electrode members 31A, 31B, 31C which are bilaterally arranged in side-by-side relation. The rear-side second electrode row 32X is comprised of three (n pieces) electrode members 32A, 32B, 32C which are bilaterally arranged in side-by-side relation in such a manner as to be parallel to the first electrode row 31X. A slit-like row-to-row gap 33s, which is linearly extended leftward and rightward, is formed between those first and second electrode rows 31X, 32X.

The electrode members 31A through 32C are each formed of an elementary substance of metal such as copper and aluminum, a metal alloy such as stainless steel and bronze, and a conductive member such as intermetallic compounds. The electrode members 31A through 32C each have a bilaterally elongate thick and flat plate-like configuration. Their bilateral length is about one third (1/n) the bilateral width dimension of the workpiece W. The length of the entire electrode row consisting of three electrode members and thus, the length of the row-to-row gap 33s is slightly longer than the width dimension of the workpiece W.

The lengths of the electrode members 31A through 32C are, for example, fifty-odd cm, respectively. By arranging three electrode members in side-by-side relation in the longitudinal direction, an effective processing width of about 1.5 m can be formed for the entire electrode unit 30X.

The lengths of the respective electrode members may be different from one another but the lengths of the opposing electrode members are desirously equal to each other.

As shown in FIGS. 1 and 2, a solid dielectric layer 34 composed of a thermally sprayed film such as alumina is coated on each of the electrode members 31A through 32C for the sake of prevention of electric arc discharge. (In FIG. 3 and afterward, the solid dielectric layer 34 is not shown, where appropriate.)

The solid dielectric layer 34 covers the front surface opposing to the counterpart row, both end faces in the longitudinal direction and upper and lower surfaces of each electrode member. The solid dielectric layer 34 is further extended from those surfaces to the four sides of the rear surface. The solid dielectric layer 34 is preferably about 0.01 to 4 mm in thickness. Besides alumina, other plate-like, sheet-like or film-like material such as ceramics and resin may be used so as to be coated on the outer peripheral surface of the electrode member. The width of the solid dielectric layer 34 at the rear surface is preferably 1 mm or more, and more preferably 3 mm or more. In FIGS. 1 and 2, the thickness of the solid dielectric layer 34 is shown in an exaggerated manner.

The corners of the respective electrode members 31A through 32C are R-chamfered for the sake of prevention of electric arc discharge. The radius of curvature of this R is preferably 1 to 10 mm and more preferably 2 to 6 mm.

As shown in FIG. 2, the electrode members 31A and 32A; 31B and 32B; and 31C and 32C bilaterally arranged in the same positions in the two electrode rows 31X, 32X are faced with each other in the back and forth directions, respectively.

That is, the electrode member 31A and electrode member 32A which are arranged on the left side of the electrode unit 30X are faced with each other in the back and forth directions. The row-to-row partial gap 33p, which serves as a left-side part of the row-to-row gap 33s, is formed between those electrode members 31A, 32A. The electrode member 31B and electrode member 32B which are arranged at the central positions are faced with each other in the back and forth directions, and the row-to-row partial gap 33p, which serves as a central part of the row-to-row gap 33s, is formed between those electrode members 31B, 32B. The electrode member 31C and electrode member 32C which are arranged on the right side are faced with each other in the back and forth directions, and the row-to-row partial gap 33p, which serves as a right-side part of the row-to-row gap 33s, is formed between those electrode members 31C, 32C. The thickness (distance between the opposing electrode members in the back and forth directions) of each row-to-row partial gap 33p is preferably about 1 mm to 3 mm and more preferably about 1 mm to 2 mm.

At the boundary between the left-side row-to-row partial gap 33p and the central row-to-row partial gap 33p, a communication space 33r is formed by corners of the four electrode members 31A, 31B, 32A, 32B. The left-side row-to-row partial gap 33p and the central row-to-row partial gap 33p are linearly communicated with each other through the communication space 33r. Likewise, at the boundary between the central row-to-row partial gap 33p and the right-side row-to-row partial gap 33p, a communication space 33r for intercommunicating those row-to-row gaps 33p, 33p is formed by the four electrode members 31B, 31C, 32B, 32C.

The row-to-row gap 33a is constituted by the three left-side, central part and right-side row-to-row gaps 33p and the two communication spaces 33r intercommunicating those gaps 33p.

As shown in FIG. 1, the entire length of the upper end opening of this row-to-row gap 33s is connected to the gas introduction port 43a, while the entire length of the lower end opening is connected to the jet port 49a.

It is also accepted that the lower plate or jet port formation member 49 is omitted, the lower end opening itself of the row-to-row gap 33s constitutes the jet port and the processing gas is directly jetted out through the lower end opening of this row-to-row gap 33s.

As shown in FIG. 2, an in-row gap 33q is formed between the left-side electrode member 31A and the central-part electrode member 31B adjacent to the member 31A in the first electrode row 31X. This in-row gap 33q is connected to the left-side communication space 33r. The in-row gap 33q is also formed between the central-part electrode member 31B and the right-side electrode member 31C, and this in-row gap 33q is connected to the right-side communication space 33r.

Likewise, in-row gaps 33q are also respectively formed between every adjacent electrode members 32A, 32B, 32C in the second electrode row 32X, and this in-row gap 33q is connected to the corresponding communication space 33r.

The surfaces of the respective electrode members 31A through 32C for forming the in-row gaps 33q are at a right angle to the surfaces of the members 31A through 32C for forming the row-to-row gaps 33p. The in-row gap 33q is orthogonal to the row-to-row gap 33s. The in-row gap 33q is preferably about 1 to 3 mm in thickness.

A small spacer 36 for keeping the interval between every adjacent electrode members is disposed at each in-row gap 33q. The spacer 36 is formed of an insulating and plasma resistant material such as ceramic. The spacer 36 is arranged in such a manner as to be one-sided to the rear surface (one-sided to the side farther from the other electrode row) of each electrode member, thereby ensuring the in-row gap 33q as a space. The depth of the rn-row gap 33q as a space (the width of the spacer 36 is subtracted) is, for example, about 5 mm. The thickness (distance between the bilaterally adjacent electrode members) of the in-row gap 33q may be approximately equal to the in-row gap 33q or row-to-row partial gap 33p, or larger than the gap 33q or 33s by, for example, about 1 mm to 3 mm.

As shown in FIG. 2, the electrode unit 30X is of a staggered pole arrangement construction. That is, one of the electrode members, which are faced with each other in the back and forth directions, serves as an electric field applying electrode and the other, as a grounding electrode, respectively. Thus, those electrode members have opposite polarities with respect to each other. Moreover, the electrode members, which are bilaterally adjacent to each other, also have opposite polarities.

Specifically, in the left-side part of the electrode unit 30X, the front-side electrode member 31A is connected to the pulse power source 3A through the power feed line 3a, while the rear-side electrode member 32A is grounded through an earth line 3e. Owing to this arrangement, a pulse electric field is formed in the left-side row-to-row partial gap 33p of the electrode unit 30X by pulse voltage supplied by the power source 3A and a glow discharge is generated therein.

In the central part of the electrode unit 30X, the electrode member 31B is grounded through the earth line 3e, while the electrode member 32B is connected to the pulse power source 3B through a power feed line 3b. Owing to this arrangement, a pulse electric field is formed in the central row-to-row partial gap 33p by pulse voltage supplied by the power source 3B and a glow discharge is generated therein.

In the right-side part of the electrode unit 30X, the electrode member 31C is connected to the pulse power source 3C through the power feed line 3e, while the electrode member 32C is grounded through the earth line 3e. Owing to this arrangement, a pulse electric field is formed in the right-side row-to-row partial gap 33p by the pulse voltage supplied by the power source 3C and a glow discharge is generated therein.

Owing to the above-mentioned arrangement, the three row-to-row partial gaps 33p of the electrode unit 30X each serve as a part of a discharge space, and thus, the general entire row-to-row gap 33s serves as a discharge space.

Moreover, a pulse electric field is likewise formed in each of the four in-row gaps 33q by voltage supplied by the power sources 3A, 3B, 3C and a glow discharge is generated therein. Owing to this arrangement, the row-in gap 33q also serves as a part of the discharge space of the electrode unit 30X. Those row-in gaps 33q connect the disconnection parts between the left-side and central row-to-row partial gaps 33p and between the central and right-side row-to-row partial gaps 33p, respectively, thereby continuously forming the discharge space over the bilaterally entire length of the electrode unit 30X.

The three electrode members 31A, 32B, 31C forming the electric field applying electrodes are connected to different power sources 3A, 3B, 3C, respectively.

If the left-side part of the electrode unit 30X is referred to as the “first position” and the left-side row-to-row partial gap 33p as the “first row-to-row partial gap”, respectively, the central part can be referred to as the “second position adjacent to the first position” and the central row-to-row partial gap 33p as the “second row-to-row partial gap”, respectively.

If the central part of the electrode unit 30X is referred to as the “first position” and the central row-to-row partial gap 33p as the “first row-to-row partial gap”, respectively, the left-side part or the right-side part can be referred to as the “second position adjacent to the first position” and the left-side or right-side row-to-row partial gap 33p as the “second row-to-row partial gap”, respectively.

If the right-side part of the electrode unit 30X is referred to as the “first position” and the right-side row-to-row partial gap 33p as the “first row-to-row partial gap”, respectively, the central part can be referred to as the “second position adjacent to the first position” and the central row-to-row gap part 33p as the “second row-to-row partial gap”, respectively.

As shown in FIG. 1 (not shown in FIG. 2 and other succeeding FIGS.), the nozzle head 1 is provided at the discharge processor 30 with a pull bolt (pull screw member) 601 hooked on a side plate 42 of the frame 40 through a resin-made bolt collar 603 and screwed into the respective electrode members 31A through 32C to pull the electrode members outwardly in the back and forth directions, and a push bolt (push screw member) 602 for pushing the electrode members inwardly in the back and forth directions through a holder 48. The pull bolt 601 and the push bolt 602 are arranged at an interval in the bilateral direction. The back and forth position of the respective electrode members 31A through 32C and thus, the thickness of the row-to-row gap 33s can be adjusted by those bolts 601, 602. Those push/pull bolts 601, 602 are also functioned as a prohibition means for bending caused by Coulomb force of the electrode members 31A through 32C. The electrode members 31A through 32C are each preferably provided with two or more sets of the push/pull bolts 601, 602.

Operation of the remote type normal pressure plasma processing apparatus thus constructed will be described.

The processing gas bilaterally uniformized in the processing gas introduction part 20 is introduced in the longitudinal direction of the row-to-row gap 33s of the electrode unit 30X via the introduction port 43a. In parallel with this, pulse voltage is supplied to the electrode members 31A, 32B, 31C from the power sources 3A, 3B, 3C, respectively. By doing so, a pulse electric field is formed in each row-to-row partial gap 33p, a glow discharge occurs therein and the processing gas is plasmatized (excited/activated). The processing gas thus plasmatized is uniformly jetted through each row-to-row partial gap 33p in the jet port 49a. By doing so, as shown in FIG. 3, plasma is applied to a region R1 corresponding to each row-to-row partial gap 33p on the upper surface of the glass substrate W so that surface processing can be conducted.

A part of the processing gas coming from the introduction port 43a is introduced into the communication space 33r and flown into the in-row gap 33q therefrom. A glow discharge is also occurred in this in-row gap 33q by supply of pulse voltage from the power source and the processing gas is plasmatized. The processing gas thus plasmatized in the in-row gap 33q is jetted from a part corresponding to the communication space 33r in the jet port 49a. By doing so, as shown in FIG. 3, plasma can also be sprayed onto the region R2 corresponding to the communication space 33r in the glass substrate W. By doing so, the glass substrate W having a large area can be generally uniformly plasma surface processed over the bilaterally entire width without any irregularity.

Simultaneously, the entire surface of the glass substrate W can be processed by moving the glass substrate W back and forth by a carrier means 4.

Even though the entire electrode unit 30X has a length corresponding to the width dimension of the glass substrate W, each electrode member 31A through 32C has a length equal to about a third (a fraction) thereof and therefore, dimensional accuracy can easily be obtained. In addition, even if Coulomb force is acted hard by application of electric field and a thermal stress is generated by difference in thermal expansion coefficient between the metal main body constituting the electrode members 31A through 32C and the solid dielectric 34 disposed at the surface thereof, the bending amount can be restrained. Owing to this arrangement, the width of the row-to-row partial gap 33p can be held constant. Accordingly, flow of the processing gas can be held uniformly in the row-to-row partial gap 33p and thus, uniformity of surface processing can be obtained. Moreover, there is no need of enlarging the thickness of the electrode members in order to increase the rigidity, a load applicable to the support structure can be reduced by avoiding weight increase and the material cost, etc. can be prevented from increasing.

Since the power sources 3A, 3B, 3C are employed for the small electrode members 31A, 32B, 31C, respectively, the supply of power per unit area can sufficiently be increased even if the capacity of each power source 3A, 3B, 3C is small. Thus, the processing gas can sufficiently be plasmatized and a high processing performance can be obtained. Moreover, since the power sources 3A, 3B, 3C are connected to separate electrode members, respectively, they are not required to be synchronized with each other. In addition, since polarities are arranged in a staggered manner and the electric field applying poles are not bilaterally adjacent to each other, there is no fear that an electric arc is generated by abnormal electric field formed between the adjacent electrode members even if the power sources 3A, 3B, 3C are not synchronized with each other.

Other embodiments of the present invention will be described next. In the embodiments to be described hereinafter, the same components as in the above-mentioned embodiment are properly denoted by same reference numeral in the drawings and description thereof is simplified.

In an embodiment shown in FIGS. 4 and 5, a gas guiding member 51 constituting a “gas guide” is received in each row-to-row partial gap 33p. This gas guiding member 51 is arranged at a part near the adjacent (second position) row-to-row partial gap in each first row-to-row partial gap 33p. That is, in the left-side row-to-row partial gap 33p, the gas guiding member 51 is arranged at its right-side part. In the central row-to-row partial gap 33p, the gas guiding members 51 are arranged at both left and right-side parts thereof, respectively. In the right-side row-to-row partial gap 33p, the gas guiding member 51 is arranged at its left-side part.

The gas guiding member 51 is formed of an insulating and plasma resistant material such as ceramics and has a wedge-like configuration (elongate triangular configuration) facing upward. That is, the gas guiding member 51 includes a vertical surface, a gas guiding surface 51a inclined downward to the adjacent side (direction toward the second position) at an acute angle with this vertical surface and a bottom surface connecting the lower ends of those two surfaces. The bilateral width of the bottom surface of the gas guiding member 51 is preferably 5 mm or less.

As indicated by arrows of FIG. 5, a gas flow f0, of all the processing gas flowing into the row-to-row gap 33s from the introduction port 43a, which is passed through a part other than the part (part near the second position) near the adjacent in the row-to-row partial gap 33p in each first position, is flowed directly downwardly. On the other hand, the gas flow f1 passing through the part near the adjacent in the row-to-row partial gap 33p of each first position is introduced in the adjacent direction along the guiding surface 51a of the gas guiding member 51. The processing gas is plasmatized during this process. The plasmatized gas flow f1 is jetted through the jet port 49a via the communication space 33r. Owing to this arrangement, plasma can more reliably be sprayed onto the region R2 corresponding to the communication space 33r in the glass substrate W. As a result, processing irregularity can more reliably be prevented from occurring, and uniformity of surface processing can be more enhanced.

Of the gas flow f0 in the row-to-row partial gap 33p of each first position, a part f2 of the gas flow flowing immediately downwardly along the vertical surface of the gas guiding member 51 is flowed around to the lower side of the gas guiding member 51. This makes it possible to reliably conduct the plasma processing even at the place corresponding to the lower side of the gas guiding member 51, and uniformity of processing can be more enhanced.

According to experiment conducted by the inventors, the time required for empty discharge could be reduced in the empty discharge process which was conducted for heating the electrodes, etc., before processing.

FIG. 6 shows a modified embodiment of the gas guiding member. This gas guiding member 52 is provided with a gas guiding surface 52a inclined downwardly to the adjacent side (direction toward the second position) from the apex angle and a gas return surface 52b inclined downwardly to the opposite side to the adjacent side from the lower end of the gas guiding surface 52a.

According to this gas guiding member 52, a part f3 of the gas flow f1 introduced in the adjacent direction along the gas guiding surface 52a can reliably be returned to the opposite side along the gas return surface 52b and can reliably be flown around to the lower side of the gas guiding member 52. Owing to this arrangement, plasma processing can also be reliably conducted immediately under the gas guiding member 52 and uniformity of processing can be more enhanced.

The gas guiding member is not limited to the configurations shown in FIGS. 5 and 6 but it may have other various configurations as long as they can introduce the gas flow near the second position of the first row-to-row partial gap 33p to the adjacent second position. For example, the gas guiding member may have a configuration resembling a regular triangular configuration in section as the gas guiding member 53 shown in FIG. 7 or a flat plate-like configuration inclined downwardly in the adjacent direction as the gas guiding member 54 shown in FIG. 8. In those members 53, 54, the slantwise surfaces inclined downwardly in the adjacent direction (direction toward the second position) constitute the gas guiding surfaces 53a, 54a, respectively.

In an embodiment shown in FIG. 9, the gas guide for introducing the gas flow in the adjacent direction is disposed at a gas introduction port forming part 43 on the upper side (processing gas introduction side) from the electrode unit 30X. Specifically, an introduction port of the processing gas introduction port forming part 43 is constituted by a large number of tiny branch ports 43b, 43c arranged at short intervals in the bilateral direction instead of the bilaterally elongate slit 48a of the first embodiment. Of those branch ports 43b, 43c, the branch port 43c corresponding to the middle part of the row-to-row partial gap 33p is open immediately downwardly. On the other hand, the branch port 43b corresponding to the side part (part near the second position) near the adjacent of each first row-to-row partial gap 33p is inclined in the adjacent direction (direction toward the second position). This inclination branch port 43b constitutes the “gas guide”.

Of all the processing gas, the gas flow f0 passing through the vertical branch port 43c is plasmatized while flowing immediately downwardly through the row-to-row partial gap 33p and then sprayed onto the glass substrate W.

On the other hand, the gas flow f1 passing through the inclination branch port 43b is flown slantwise downwardly in the adjacent direction (direction toward the second position) while being plasmatized in the row-to-row partial gap 33p. Then, the plasmatized gas is jetted downwardly of the communication space 33r. Owing to this arrangement, plasma surface processing can reliably be conducted at the region R2 corresponding to the communication space of the glass substrate W, and uniformity of processing can be enhanced.

In an embodiment shown in FIG. 10, a gas introduction pipe 43P serving as the processing gas introduction port forming part is disposed at an upper part of the electrode unit 30X (only reference numeral 33B is shown). The gas introduction pipe 43P is extended along the first row-to-row partial gap 33p and curved in such a manner as to be warped upwardly at the parts corresponding to the longitudinal both left and right sides of the first row-to-row partial gap 33p. A large number of pinhole-like branch ports 43d, 43e serving as a port for introducing the processing gas into the first row-to-row partial gap 33p are formed in a lower side part of the gas introduction pipe 43P at short intervals in the longitudinal direction of the pipe 43P. The branch port 43e corresponding to the middle part of the first row-to-row partial gap 33p is open generally immediately downwardly. On the other hand, those branch ports 43e which are nearer to the both ends are more heavily inclined in the adjacent direction (direction toward the second position). The branch ports 43d located at the both ends, that is, the side parts (part near the second position) near the adjacent of the first row-to-row partial gap 33p are most heavily inclined in the adjacent directions, respectively. This branch port 43d constitutes the “gas guide”.

The processing gas is introduced to one end part of the introduction pipe 43P. This processing gas is flowed through the introduction pipe 43P and gradually leaked into the first row-to-row partial gap 33p located at a lower part from the branch ports 43d, 43e. Of all the gas, the gas flow f1′ flowed out of the branch port 43d is flown slantwise downwardly in the adjacent direction (direction toward the second position) through the first row-to-row partial gap 33p. Owing to this arrangement, plasma surface processing can be conducted at the region R2 corresponding to the communication space of the glass substrate W and uniformity of processing can be enhanced.

In an embodiment shown in FIG. 11, the opposing end faces of the respective electrode members 31A through 32C (only reference numerals 31A, 31B are shown) with respect to the bilaterally adjacent electrode members are slantwise cut, and the upper side part of each opposing end face is greatly separated from the adjacent electrode member and brought closer to the adjacent electrode downwardly. Accordingly, the communication space 33r and the in-row gap 33q are more reduced in width downwardly.

As indicated by arrows in FIG. 11, the processing gas is introduced into the row-to-row partial gap 33p generally at the same angle as that of the inclination of each end face. Owing to this arrangement, the passing distance for the processing gas through the row-to-row partial gap can be increased and processing gas can sufficiently be plasmatized.

In an embodiment shown in FIGS. 12 and 13, the processing gas introduction port forming part 43 is provided at the introduction port 43a with three (plurality) insulating resin-made flow rectification members 60 serving as the gas guide. The introduction port 43a is in the form of slit extending over the entire length, i.e., three row-to-row partial gaps 33p, of the row-to-row gap 33s. As shown in FIG. 14, each flow rectification member 60 integrally includes a base plate 61 and a plurality of flow rectification plates 62, 63 disposed at a single surface of the base plate 61. The base plate 61 is in the form of an elongate thin plate having a length corresponding to that of each row-to-row partial gap 33p. As shown in FIGS. 12 and 13, the base plate 61 is abutted with one inner side surface of the slit-like through-hole 41s of the frame upper plate 41, and three flow rectification members 60 are bilaterally arranged in a side-by-side relation in a row and received in the slit-like through-hole 41a in that condition. The flow rectification members 60 are in one-to-one correspondence with the row-to-row partial gaps 33p. The boundary between the adjacent flow rectification members 60 is in correspondence with the communication space 33r.

As shown in FIGS. 13 and 14, the flow rectification plates 62, 63 are arranged at intervals in the longitudinal direction of the base plate 61. The slit-like through hole 41a is partitioned by those flow rectification plates 62, 63. As shown in FIG. 12, the flow rectification plates 62, 63 are abutted with the inner surfaces on the opposite side of the base plate 61 in the slit-like through-hole 41a, thereby the flow rectification member 60s are firmly fixed to the interior of the through-hole 41a. As shown in FIG. 13, the flow rectification plate 62 arranged near the communication space 33r is slanted downwardly toward the adjacent flow rectification member 60. All the other flow rectification plates 63 are disposed generally in their vertical postures.

As indicated by reference numeral f0 in FIG. 13, most part of the processing gas introduced to the introduction port 43a is flowed straightly downwardly. The processing gas is hardly disturbed by the flow rectification plates 63. On the other hand, as indicated by reference numeral f1, the processing gas flow is slanted near the place where the flow rectification plate 62 is arranged, by the flow rectification plate 62. This slantwise flow f1 is passed through the part (part near the second position) near the adjacent of the first row-to-row partial gap 33p and flowed closer to the communication space 33r and thus, the adjacent second row-to-row partial gap 33p while being plasmatized. Owing to this arrangement, plasma can also be jetted to the lower side of the communication space 33r, plasma surface processing can reliably be conducted at the region R2 corresponding to the communication space of the glass substrate W and uniformity of processing can be enhanced.

The flow rectification member 60 may be disposed only at the upper part in the vicinity of the communication space 33r. Of the flow rectification plates 62, 63, the flow rectification plate 63 may be eliminated and only the flow rectification plate 62 may be employed.

In the embodiment shown in FIGS. 12 and 13, although the flow rectification member 60 is disposed only in the through-hole 41a of the upper plate 41 of the frame 40, it may be disposed at the gap 48a of the holder 48.

In an embodiment shown in FIGS. 15 and 16, a blocking member (blocking part) 70 formed of an insulating resin is fitted to the introduction port 43a of the processing gas introduction port forming part 43. The blocking member 70 is arranged at a part (boundary between the first row-to-row partial gap and the second row-to-row partial gap) corresponding to the communication space 33r in the introduction port 43a in such a manner as to be astride adjacent two row-to-row partial gaps 33p. The end part on the introduction port 43a side of the communication space 33r is blocked with this blocking member 70. The communication space 33r on the jet port side is made open by the blocking member 70 and communicated with the introduction port 43a through the two row-to-row partial gaps 33p adjacent thereto.

As indicated by reference numeral f1 in FIG. 15, the processing gas passing through a part near the communication space 33r (thus, near the second row-to-row partial gap 33p) of the first row-to-row partial gap 33p is plasmatized and then, flown into the communication space 33r in such a manner as to flow around to the lower side of the blocking member 70. Owing to this arrangement, plasma can also be jetted to the lower side of the communication space 33r, plasma surface processing can reliably be conducted at the region R2 corresponding to the communication space of the glass substrate W and uniformity of processing can be enhanced.

In an embodiment shown in FIGS. 17 through 19, the spacer 36 of FIG. 2 is modified so as to be provided as the “gas guide”. As shown in FIGS. 17 and 19, a gate-shaped spacer 80 formed of an insulating resin is inserted in the boundary between the bilaterally adjacent electrode members of the electrode structure 30X. That is, the gate-shaped spacers 80 are each sandwiched between the left-side electrode members 31A, 32A and the central part electrode members 31B, 32B and between the central part electrode members 31B, 32B and the right-side electrode members 31C, 32C, respectively.

As shown in FIG. 18, the spacer 80 includes a pair of leg parts 81 and a connection part 82 for connecting the upper end parts of those leg parts 81 to each other and has a gate-shaped flat plate-like configuration. The outer contour of the gate-shaped spacer 80 is coincident with the contour of the side section of the entire electrode unit 30X. As shown in FIG. 19, one of the pair of leg parts 81 is sandwiched between the adjacent first electrode members of the first electrode row 31X and the other leg part 81 is sandwiched between the adjacent second electrode members of the second electrode row 32X. Those leg parts 81 serve as the “interposing part between the adjacent electrode members”.

The leg parts 81 of the spacer 80 are arranged near the back surface (near the side apart from the other electrode row) of the electrode member, thereby the in-row gap 33q as a space is obtained. It is also accepted that the leg parts 81 are equal in width to the electrode members 31A through 32C so that in-row gap 33q is completely filled with the leg parts 81.

As shown in FIGS. 17 and 18, the connection part 82 is arranged near the upper side of the in-row gap 33q and communication space 33r, i.e., near the introduction port 43a side. The end part on the introduction port 43a side of the communication space 33r is blocked with this connection part 82. The communication space 33r on the jet port side from the connection part 82 is open and communicated with the introduction port 43a through the row-to-row partial gaps 33p adjacent thereto. The connection part 82 is provided as the “blocking part for blocking the end part on the introduction port side of the boundary between the first row-to-row partial gap and the second row-to-row partial gap and open the blow port side therefrom”.

As indicated by reference numeral f1 in FIG. 17, the processing gas is passed through the row-to-row partial gaps 33p on the both sides of the connection part 82 and plasmatized therein and then, flown into the communication space 33r on the lower side from the connection part 82. Owing to this arrangement, plasma surface processing can reliably be conducted at the region R2 corresponding to the communication space of the glass substrate W and uniformity of processing can be enhanced. Moreover, by making the adjacent electrode members different in polarities with each other in the respective electrode rows 31X, 32X, the in-row gap 33p can serve as a part of the discharge space and the processing gas can also be plasmatized therein. Owing to this arrangement, plasma surface processing can more reliably be conducted at the region R2 corresponding to the communication space of the glass substrate W and uniformity of processing can be more enhanced.

In an embodiment shown in FIGS. 20 and 21, the “gas guide” is disposed at the lower side (jet port side) from the electrode unit 30X. That is, the lower plate 49 is provided at its bilaterally elongate slit-like jet port 49a with a gas guiding part 49B as the gas guide at a position corresponding to the side part (part near the second position) near the adjacent of each first row-to-row partial gap 33p. The gas guiding part 49B is integral with the lower plate 49. The gas guiding part 49B has a triangular configuration in section having a gas guiding surface 49c inclined downwardly toward the adjacent side (direction toward the second position) and bridge between the front and rear edge surfaces of the jet port 49a.

As shown in FIG. 21, of the processing gas plasmatized in the first row-to-row partial gap 33p, the gas flow f1″ flowing out of the side part (part near the second position) near the adjacent is introduced in the adjacent direction (direction toward the second position) by the gas guiding surface 49c of the gas guiding part 49B. Owing to this arrangement, plasma surface processing can be conducted at the region R2 corresponding to the communication space of the glass substrate W and uniformity of processing can be enhanced.

In an embodiment shown in FIGS. 22 and 23, a porous plate 90 having a large number of apertures 90a is fitted into a slit-like jet port 49a of the lower plate 49 as the gas guide. The porous plate 90 arranged slightly away downwardly from the electrode unit 30X and near the lower side part of the jet port 49a.

The processing gas coming from the row-to-row partial gap 33s is dispersed in an upper side space 49g from the porous plate 90 of the jet port 49a and uniformized therein. Accordingly, as indicated by reference numeral f1 in FIG. 23, a part of the processing gas plasmatized in each row-to-row partial gap 33p is also dispersed to the lower side of the communication space 33r. Then, the gas is uniformly jetted out of the large number of apertures 90a. Owing to this arrangement, uniformity of processing can be enhanced.

In an embodiment shown in FIGS. 24, 25 and 26, the lower plate 49 serving as the jet port forming part of the discharge processor 30 is constituted by two upper and lower plate parts 49U, 49L. Three slit-like upper stage jet ports 49d corresponding to the respective row-to-row partial gaps 33p are formed in a row at the upper stage plate part 49U. The left-side upper stage jet port 49d and the central upper stage jet port 49d are cut off by a bridge part 49E. Similarly, the central upper stage jet port 49d and the right-side upper stage jet port 49d are cut off by another bridge part 49E.

Each upper stage jet port 49d is directly connected to the upper-side row-to-row partial gap 33p. Width of the upper stage jet port 49d is larger than the width of the row-to-row partial gap 33p.

A lower stage jet port 49f having a length generally equal to the entire length of the row-to-row gap 33s is formed in the lower stage plate part 49L. The width of the lower stage jet port 49f is smaller than the width of the upper stage jet port 49d and generally equal to the width of the row-to-row partial gap 33p.

The bridge part 49E is arranged immediately under the communication space 33r. The lower end of the communication space 33r is blocked with this bridge part 49E. Owing to this arrangement, the bridge part 49E constitutes the “blocking part for blocking the end part on the jet port side of the boundary between the adjacent tow-to-row partial gaps of the jet port”. The lower stage jet port 49f is arranged below the bridge part 49E. That is, the bridge part 49E is arranged near the upper side in the entire jet port composed of the upper and lower stages jet ports 49d, 49f. The communication space 33r is communicated with the jet ports 49d, 49f only through the row-to-row partial gaps adjacent thereto.

The plate parts 49U, 49L may be integral with each other, and the jet port forming member may be constituted by laminating three or more plate parts instead of two.

As indicated by reference numeral f1 in FIG. 26, the processing gas coming down within the communication space 33r is prohibited from flowing directly to the jet port from the communication space 33r by the bridge part 49E and necessarily flowed through the row-to-row partial gaps adjacent thereto and plasmatized therein and then, the plasmatized gas is flown into the jet port 49d. The plasmatized gas is then flown around to the lower stage jet port 49f on the lower side of the bridge 49E and jetted thereunder. Owing to this arrangement, plasma surface processing can be conducted at the region R2 corresponding to the communication space and uniformity of processing can be enhanced.

FIGS. 27 and 28 show a modified embodiment of a jet port 49a formed in the lower plate 49 of the plasma processing apparatus. A row-to-row jet port 49h extending long in the bilateral direction and two short in-row jet ports 49i extending back and forth in such a manner as to intersect with the row-to-row jet port 49h at two places of its middle part are formed in the lower plate 49. The row-to-row jet port 49h is connected to the lower end part of the row-to-row gap 33s over its entire length. One of the two in-row jet ports 49i is arranged just at the boundary between the left-side electrode members 31A, 32A and the central electrode members 31B, 32B and connected to the in-row gap 33q between those electrode members and the lower end part of the communication space 33r. The other in-row jet port 49i is arranged just at the boundary between the central electrode members 31B, 32B and the right-side electrode members 31C, 32C and connected to the in-row gap 33q between those electrode members and the lower end part of the communication space 33r. Owing to this arrangement, the jet port of the lower plate 49 becomes larger in opening width at the part corresponding to the boundary between the adjacent row-to-row partial gaps 33p than at the part corresponding to each row-to-row partial gap 33p and is reduced in flow resistance.

The processing gas plasmatized in the in-row gap 33q is jetted out of the in-row jet port 49i connected to immediately under of the in-row gap 33q. The processing gas coming out of the side part (part near the second position) near the adjacent of each first row-to-row partial gap 33p is jetted while being flown toward the in-row jet port 49i having a small flow resistance. Owing to this arrangement, uniformity of processing can be enhanced. The in-row jet port 49i (jet port part of the large opening corresponding to the boundary between the first and second row-to-row partial gaps) of the jet port 49a constitutes the “gas guide”.

The in-row jet port 49i is effective in an arrangement wherein the entire in-row gap 33q is filled with the insulating spacer so that the processing gas can pass only through the row-to-row gap 33s, or in an arrangement wherein the electrode members adjacent to each other with the in-row gap 33q disposed therebetween have the same polarity so that no discharge can occur in the in-row gap 33q as in an embodiment (FIGS. 40 and 41, as well as elsewhere) as later described. That is, the processing gas plasmatized in the respective row-to-row partial gaps 33p attempts to flow into the in-row jet port 49i having a large opening and a small flow resistance, thereby uniformity of processing gas can be obtained.

The length of the in-row jet port 49i can properly be increased or reduced and is not required to be made coincident with the length of the in-row gap 33q.

Moreover, as shown in FIG. 29, the in-row jet port 49i may be disposed at only one side (for example, the second electrode row 32X side) of the row-to-row jet port 49h.

The in-row jet port 49i may be combined with the gas guiding part 49B, etc. of FIG. 20.

It is also accepted that the lower plate or jet port forming member 49 is eliminated, the in-row gap 33q and the lower end opening itself of the row-to-row gap 33s constitute the jet port and the processing gas is jetted directly therethrough.

The configuration of the jet port part of the large opening corresponding to the boundary between the first and second row-to-row partial gaps 33p is not limited to the slit-like configuration as in the case with the in-row jet port 49i. For example, as an opening 49j shown in FIG. 30(a), it may be a diamond-like configuration or as an opening 49k shown in FIG. 30(b), it may be a triangular configuration protruding toward one side of the row-to-row jet port 49h. It may also have other various configurations such as a circular configuration.

FIGS. 31 and 32 show a modified embodiment of the gas guide or introduction port forming part 43. A processing gas introduction port 43a connected to a chamber 24 in a lower end of a processing gas introduction part 20 not shown is formed in the introduction port forming part 43. The processing gas introduction port 43a includes a row-to-row introduction port (main introduction port) extending long in the bilateral direction and cut-off shaped in-row introduction ports (auxiliary introduction ports) 43i formed on the both sides of two places at the middle part of this row-to-row introduction port 43h.

The lower end part of the row-to-row introduction port 43h is directly connected to the row-to-row gap 33s over its entire length.

The in-row introduction ports 43i are each arranged at the boundary between the adjacent electrode members 31A, 31B and at the boundary between the adjacent electrode members 31B, 31C of the first electrode row 31X, and at the boundary between the adjacent electrode members 32A, 32B and at the boundary between the adjacent electrode members 32B, 32C of the second electrode row 32X, and they are directly connected to the upper end part of the in-row gap 33q between those electrode members.

The processing gas uniformized in the processing gas introduction part 20 is introduced into the respective row-to-row partial gaps 33p from the row-to-row introduction port 33q and directly introduced into the in-row gaps 33q from the in-row introduction ports 43i. Owing to this arrangement, the processing gas directly introduced into the in-row gap 33q can be plasmatized without deflecting the processing gas plasmatized in the respective first row-to-row partial gaps 33p toward the boundary between the first row-to-row partial gap 33p and the second row-to-row partial gap 33p, and an amount of plasma can reliably be obtained at the boundary between the first and second row-to-row partial gaps 33p. As a result, uniformity of processing can be enhanced.

The length of the in-row introduction port 43i may properly be increased or reduced and is not required to be made coincident with the length of the in-row gap 33q. Moreover, the in-row introduction port 43i may be disposed at only one side of the both front and back sides of the row-to-row introduction port 43h.

In the present invention, the electrode members 31A and 32A; 31B and 32B; and 31C and 32C of two electrode rows 31X, 32X are not required to be correctly faced with each other in the back and forth directions but they are required to be faced with each other at the substantially same position. For example, in an embodiment shown in FIG. 33, the electrode members 31A through 31C of the first electrode row 31X and the electrode members 32A through 32C of the second electrode row 32X are slightly deviatedly arranged in the bilateral direction.

The deviating arrangement construction of FIG. 33 may be applied to the electrode structure having an alternating polarity arrangement of FIG. 2 as well as elsewhere, and it may also be applied to an electrode structure having the same polarity per each row as in FIGS. 40 and 41, as well as elsewhere, as later described. According to the experiment conducted by the inventors, the entire area of the workpiece W in the width direction could be processed even if two rows are slightly deviated with each other not only in the case of the same polarity structure per each row but also in the case of the alternating polarity structure.

In the embodiments described hereinbefore, the in-row gap 33q is orthogonal to the row-to-row gap 33s but the former may be inclined with respect to the latter as shown in FIGS. 34 and 35. Of all the left and right two electrode members of the first electrode row 31X, the in-row gap 33q forming surface (second surface) of the left-side electrode member 31A is disposed at an obtuse angle of, for example, 150 degrees with respect to the row-to-row gap 33s forming surface (first surface). On the other hand, the in-row gap 33q forming surface (fourth surface) of the right-side electrode member 31B is disposed at an acute angle of, for example, 30 degrees with respect to the row-to-row gap 33s forming surface (third surface). Owing to this arrangement, the in-row gap 33q of the first electrode row 31X is declined rightwardly at an angle of, for example, 30 degrees with respect to the row-to-row gap 33s away from the row-to-row gap 33s.

Similarly, of all the left and right two electrode members of the second electrode row 32X, the in-row gap 33q forming surface (fourth surface) of the left-side electrode member 32A is disposed at an acute angle of, for example, 30 degrees with respect to the row-to-row gap 33s forming surface (third surface), and the in-row gap 33q forming surface (second surface) of the right-side electrode member 32B is disposed at an obtuse angle of, for example, 150 degrees with respect to the row-to-row gap 33s forming surface (first surface). Owing to this arrangement, the in-row gap 33q of the second electrode row 32X is declined leftwardly at an angle of, for example, 30 degrees with respect to the row-to-row gap 33s away from the row-to-row gap 33s.

The inclination angle of the in-row gap 33q is preferably about 30 to 60 degrees. The thicknesses of the row-to-row gap 33p and in-row gap 33q are each preferably about 1 to 3 mm. The lengths of the electrode members 31A, 31B, 32A, 32B are each about 1 m, and an effective processing width of about 2 m is formed over the entire electrode unit 30X by arranging two electrode members in the longitudinal direction.

As shown in FIG. 36(a) on an enlarged basis, in the first electrode row 31X, the obtuse corner 31d formed between the row-to-row gap forming surface (first surface) and the in-row gap forming surface (second surface) of the left-side electrode member 31A is R-chamfered with a relatively large radius of curvature. The acute corner 31e formed between the row-to-row gap forming surface (third surface) and the in-row gap forming surface (fourth surface) is R-chamfered with a relatively small radius of curvature. Though not shown, in the second electrode row 32X, the acute corner 32e formed between the row-to-row gap forming surface (third surface) and the in-row gap forming surface (fourth surface) of the left-side electrode member 32A is R-chamfered with a relatively small radius of curvature, and the obtuse corner 32d formed between the row-to-row gap forming surface (first surface) and the in-row gap forming surface (third surface) of the right-side electrode member 32B is R-chamfered with a relatively large radius of curvature. For example, the radius of curvature of the obtuse corners 31d, 32d is about 40 mm and the radius of curvature of the acute corners 31e, 32e is about 3 mm.

Not only the acute angle or obtuse angle but also all corner parts of the respective electrode members 31A, 31B, 32A, 32B are R-chamfered.

The radius of curvature is preferably reduced in difference as the inclination angle of the in-row gap 33q is nearer to 90 degrees. For example, as shown in FIG. 36(b), when the angle formed between the in-row gap 33q and the row-to-row gap 33s is about 45 degrees, if the radius of curvature of the corner 31e on the acute angle side is 3 mm, the radius of curvature of the corner 31d on the obtuse angle side is preferably about 40 mm. As shown in FIG. 36(c), when the angle formed between the in-row gap 33q and the row-to-row gap 33s is about 60 degrees, if the radius of curvature of the corner 31e on the acute angle side is 3 mm, the radius of curvature of the corner 31d on the obtuse angle side is preferably about 8 mm.

As shown in FIGS. 35 and 36(a), the row-to-row gap 33s forming surface of the electrode member 32A on the left side of the second electrode row 32X is arranged astride the row-to-row gap 33s forming surface (first surface) of the left-side electrode member 31A and the row-to-row gap 33s forming surface (third surface) of the right-side electrode member 31B of the first electrode row 31X.

Similarly, the row-to-row gap 33s forming surface of the right-side electrode member 31B of the first electrode row 31X is arranged astride the row-to-row gap 33s forming surface (first surface) of the right-side electrode member 32B and the row-to-row gap 33s forming surface (third surface) of the left-side electrode member 32A of the second electrode row 32X.

Owing to the above-mentioned arrangement, an intersecting part 33u between the in-row gap 33q and the row-to-row gap 33s of the first electrode row and an intersecting part 33v between the in-row gap 33q and the row-to-row gap 33v of the second electrode row are deviated in the bilateral direction. In four corner parts 31d, 31e, 32e, 32d which define the respective intersecting parts 33u, 33v, two obtuse corner parts 31d, 32d are arranged outside in the bilateral direction, and the remaining two acute corner parts 31e, 32e are arranged between the obtuse corner parts 31d, 32d.

As shown in FIG. 35, a row-to-row jet port 49m extending long in the bilateral direction and a pair of in-row jet ports 49n disposed at the both sides of the central part of this row-to-row jet port 49m in a cut-off fashion are formed in the lower plate 49. The row-to-row jet port 49m is coincident with the lower end part of the row-to-row gap 33s and connected to its entire length. The in-row jet port 49n on the first electrode row 31X side is inclined rightwardly at an angle of, for example, 30 degrees, away from the row-to-row jet port 49m and directly connected to the lower end part of the inclination in-row gap 33q of the first electrode row 31X. The in-row jet port 49n on the second electrode row 32X side is inclined leftwardly at an angle of, for example, 30 degrees away from the row-to-row jet port 49m and directly connected to the inclination in-row gap 33q of the second electrode row 32X. The lower plate 49 may be eliminated.

According to this embodiment of FIGS. 34 through 36, since the corner 3 id formed between the row-to-row gap 33s forming surface and the rn-row gap 33q forming surface of the electrode member 31A and the corner 32d formed between the row-to-row gap 33s forming surface and the in-row gap 33q forming surface of the electrode member 32B are each an obtuse angle, a favorable glow discharge is also readily occurred at those corner parts 31d, 32d, and processing omission can be prevented from occurring at the places corresponding to those corner parts 31d, 32d.

Moreover, since the obtuse corner parts 31d, 32d are heavily R-chamfered, they can smoothly be formed as much as possible and a more favorable glow discharge is readily occurred. On the other hand, since the acute corner parts 31e, 32e of the electrode members 31B, 32A faced with the obtuse corner parts 31d, 32d are slightly R-chamfered, they are allowed to protrude as much as possible so that the intersecting parts 33u, 33v between the in-row gap 33q and the row-to-row gap 33s can be reduced. Owing to this arrangement, a favorable glow discharge can more reliably be obtained at the corner parts on the obtuse angle side. As a result, processing omission can more reliably be prevented from occurring at the places corresponding to the corner parts on the obtuse angle side.

Moreover, an arc discharge can be prevented from occurring at various corner parts of the electrode member by R-chamfering.

The processing gas plasmatized in the row-to-row partial gaps 33p is jetted through the row-to-row jet port 49m, and the processing gas plasmatized in the in-row gap 33q is directly jetted through the in-row jet port 49n. In parallel, by relatively moving the workpiece W back and forth, not only the region corresponding to the row-to-row partial gaps 33p of the workpiece W but also the region corresponding to the in-row gap 33q can reliably be plasma processed. Although a glow discharge is hard to occur at the corner parts 31e, 32e on the acute angle side and the part between two intersecting parts 33u, 33v, the regions corresponding to those parts can also reliably be plasma processed by plasma jet from the in-row gap 33q. By virtue of this feature, processing omission can totally be prevented from occurring and the entire area of the workpiece W can uniformly be processed.

The inventors conducted uniform processing experiment using the apparatus of FIGS. 34 and 35.

The center lengths of the electrode members 31A, 32B each were 987 mm, the center lengths of the electrode members 32A, 32B each were 1013 mm, the entire length of each electrode row was 2 m, and the thicknesses of those electrode members each were 30 mm. The thicknesses of the row-to-row gap 33s and in-row gap 33q were 1 mm, respectively. The inclination angle of the inclination in-row gap 33q was 30 degrees, the angles of the acute corner parts 31e, 32e of the electrode members were 30 degrees, and the angles of the obtuse corner parts 31d, 32d were 150 degrees. The radii of curvature of R of the corner acute parts 31e, 32e were 3 mm and the radii of curvature of R of the obtuse corner parts 31d, 32d were 40 mm. The solid dielectric layer 34 was a thermal spraying film of alumina having a thickness of 0.5 mm.

Power source devices of 12A, 7.5 kW were used as the power sources 3A, 3B and a pulse voltage having a frequency of 15 kHz and a peak-to-peak voltage Vpp of 15 kV was applied. An ITO substrate used for a liquid crystal panel was used as the workpiece W. The contact angle of water to the unprocessed substrate was 95 degrees. A nitrogen gas was used as a processing gas for washing the substrate W and washed the substrate W at 800 slm. The speed for conveying the substrate was 2 m per min. Total power was 4.5 kW.

After washing, the contact angle of water was measured at intervals of 3 mm with respect to the surface area of the substrate over 10 cm corresponding to the neighborhood of the intersecting parts 33u, 33v. As a result, the contact angle was 25 degrees or less at all measured points. When water was applied to the entire surface of the substrate, the surface was evenly wet. It was thus confirmed that processing omission was not occurred.

In an embodiment shown in FIGS. 37 and 38, the first electrode row 31X includes four electrode members 31A, 31B, 31C, 31D bilaterally linearly arranged in a side-by-side relation and three inclination in-row gaps 33q are formed between the adjacent first electrode members. Every two adjacent gaps of those three inclination in-row gaps are mutually oppositely inclined. That is, the central two electrode members 31B, 31C of the first electrode row 31X each have a bilaterally symmetrical trapezoidal configuration. The long sides and short sides of the adjacent electrode members 31B, 31C each having a trapezoidal configuration are mutually reversely located. Owing to this arrangement, in the first electrode row 31X, the left-side in-row gap 33q is inclined rightwardly away from the intersecting part between the left-side in-row gap 33q and the row-to-row gap 33, the central in-row gap 33q is inclined leftwardly away from the intersecting part between the in-row gap 33q and the row-to-row gap 33s, and the right-side in-row gap 33q is inclined rightwardly away from the intersecting part between the right-side in-row gap 33q and the row-to-row gap 33s.

Similarly, the second electrode row 32X includes four electrode members 32A, 32B, 32C, 32D bilaterally linearly arranged in a side-by-side relation. Every two adjacent gaps of those three inclination in-row gaps 33q formed in the second electrode members are mutually oppositely inclined. The central two electrode members 32B, 32C each have a bilaterally symmetrical trapezoidal configuration and arranged with their long sides and short sides mutually reversely located.

It is also accepted that the central electrode members 31B, 31C, 32B, 32C each have a parallelepiped configuration instead of trapezoidal configuration and the inclination directions of the three in-row gaps 33q are made coincident with one another.

As shown in FIG. 38, a row-to-row jet port 49m having a slit-like configuration and extending in the bilateral direction and coincident with the row-to-row gap 33s and in-row jet ports 49n disposed in a one-to-one relation with the inclination in-row gaps 33q are formed in the lower plate 49. The lower plate 49 is optional.

The inventors conducted uniform processing experiment using the apparatus of FIGS. 37 and 38.

The center lengths of the electrode members 31A, 32A each were 513 mm, the center lengths of the electrode members 31B, 32B each were 526 mm, the center lengths of the electrode members 31C, 32C each were 487 mm, the center lengths of the electrode members 31D, 32D each were 474 mm, the entire length of each electrode row was 2 m, and the thicknesses of those electrode members each were 30 mm. The thicknesses of the row-to-row gap 33s and in-row gap 33q were 1 mm, respectively. The inclination angle of the inclination in-row gap 33q was 30 degrees, the acute angles of the electrode members each were 30 degrees, and the obtuse angles each thereof were 150 degrees. The inclination angles of the inclined in-row gaps 33q each were 30 degrees, the acute angles of the electrode members each were 30 degrees, and the obtuse angles each thereof were 150 degrees. The radii of curvature of R of the acute corner parts were 3 mm and the radii of curvature of R of the obtuse corner parts were 40 mm. The solid dielectric layer 34 was a thermal spraying film of alumina having a thickness of 0.5 mm.

Kind of the workpiece W, kind of the processing gas, etc. were same as in the above-mentioned experiment using the apparatus of FIGS. 34 and 35. Total power was 8.9 kW.

After washing, the contact angle was 16 degrees or less at all measured points. It was thus confirmed that processing omission was not occurred.

In an embodiment shown in FIG. 39, the electrode members 31A, 32B, 31C constituting the electric field applying pole are connected to a common (single) power source 3 instead of the separate power sources 3A, 3B, 3C as in the above-mentioned embodiments. Accordingly, the plasma electric fields formed in the respective row-to-row partial gaps 33p can reliably be synchronized with each other. Of course, the gas guide can also be applied to this single power source structure.

In an embodiment shown in FIG. 40, the polarity arrangement of the electrode unit 30X is such that the electrode rows 31X, 32X each have the same pole instead of the alternating arrangement as in the above-mentioned embodiments.

That is, the electrode members 31A, 31B, 31C of the first electrode row 31X are connected to the power sources 3A, 3B, 3C, respectively and thus, they all have an electric field applying pole. On the other hand, the electrode members 32A, 32B, 32C of the second electrode row 32X all have a grounding pole. In this polarity arrangement, a glow discharge also occurs in the row-to-row partial gap 33p and the processing gas can also be plasmatized therein.

The in-row gaps 33q are fully filled with partition walls 35 composed of insulating and plasma resistant material such as ceramics and the bilaterally adjacent electrode members are insulated from one another. Owing to this arrangement, an electric arc can be prevented from occurring between the bilaterally adjacent electrodes.

It suffices if the partition walls 35 each are disposed between at least the adjacent electrode members 31A through 31C having the electric field applying pole, and the partition walls 35 are not necessarily required to be disposed between the adjacent electrode members 32A through 32C having the grounding pole. The grounded electrode members 32A through 32C may be connected.

Each first row-to-row partial gap 33p is provided at a part near the second position with a gas guiding member 51 like the one shown in FIGS. 4 and 5 as the “gas guide”. In the alternative, other types of “gas guide” as shown in other FIGURES may be employed.

In an embodiment shown in FIG. 41, in the electrode unit 30X in which each row has the same pole as in FIG. 40, the electrode members 32A through 31C having the electric field applying pole are connected to a common (single) power source 3.

Although the respective in-row gaps 33q of the embodiment shown in FIG. 41 are fully filled with the same insulating partition walls 35 as in FIG. 40, the partition walls 35 may be eliminated to open the in-row gaps 33q because the applying voltages to the electrode members 31A through 31C are reliably synchronized with one another. It is also accepted that not only the adjacent grounded electrode members 32A through 32C but also the adjacent powered electrode members 31A through 31C are directly contacted, so that the in-row gaps 33q are not formed.

As shown in FIG. 42, in the electrode unit 30X having an alternating polarity arrangement as in the first embodiment (FIG. 2), it is also accepted that the bilaterally adjacent electrode members of the respective electrode rows 31X, 32X are abutted with each other so that the in-row gaps 33q are eliminated. More specifically, each electrode member has solid dielectric layers 34e each coated on its side end faces, and the solid dielectric layers 34e, 34e on the side end faces of the adjacent electrode members are abutted with and intimately adhered to each other. Those solid dielectric layers 34e, 34e on the side end faces each have a role for serving as an insulating layer between the adjacent electrode members. The width of the communication space 33r between the adjacent row-to-row partial gaps 33p is just equal to the total thickness of the two solid dielectric layers 34e, 34e.

It is also accepted that one of the mutually abutted two electrode members is provided only at its one side end face with the solid dielectric layer 34e, and the side end face of its metal main body of the other electrode member is exposed. In that case, it is of course necessary that the solid dielectric layer 34e coated on the side end face of the afore-mentioned one electrode member alone can insulate the two electrode members.

In the embodiment of FIG. 42, it is also accepted that there is a provision of a gas guide such as the gas guiding member 51. Owing to this arrangement, plasma can be jetted even in the communication space 33r, i.e., immediately under the solid dielectric layers 34e, 34e and uniformity of processing can be improved.

In the embodiment of FIG. 42, a partition wall 35 as in FIG. 40 may be inserted between the adjacent electrode members.

In the embodiment of FIG. 42, the separate power sources 3A, 3B, 3C are provided for the electrode members 31A, 32B, 31C, respectively as in the first embodiment but a single power source 3 instead of the separate power sources 31A, 32B, 31C may be employed as in the embodiment of FIG. 39.

As shown in FIG. 43, in the electrode unit 30X having a same polarity arrangement per row as in the embodiment of FIG. 40, the adjacent electrode members of each electrode row 31X, 32X may be abutted with each other. The side end faces of each electrode member of this embodiment are not coated with the solid dielectric layers, respectively but the metal main body is exposed. Owing to this arrangement, the side end faces of the metal main bodies of the bilaterally adjacent electrode members are directly abutted with each other. The communication space 33r has hardly no size dimension and the adjacent row-to-row partial gaps 33p are generally directly connected to each other. The three power sources 3A, 3B, 3C are desirably symmetrical with one another. In case they are not symmetrical with one another, at least the electric field applying electrode members 31A through 31C of the electrode row 31X are provided on the side end faces each with the solid dielectric layer 34e as an insulating layer as in the embodiment of FIG. 42. Instead of the separate power sources 31A, 32B, 31C, a single power source 3 may be used as in the embodiment of FIG. 41. In the embodiment of FIG. 43, a gas guide such as the gas guiding member 51 may be applied.

FIG. 44 shows an example of a basic construction of a normal plasma processing apparatus according to the second feature. This apparatus comprises a pair of electric field applying electrode 100 and grounding electrode 200, two (plural) power source devices 301, 302, and a synchronizer 400 for those power source devices 301, 302.

The electric field applying electrode 100 is divided into two (plural) divided electrode members 111, 112. The divided electrode members 111, 112 each have a flat plate-like configuration and linearly bilaterally arranged in a side-by-side relation. Similarly, the grounding electrode 200 is divided into two (plural) flat plate-like divided electrode members 211, 212, and those divided electrode members 211, 212 are linearly bilaterally arranged in a side-by-side relation.

The left-side divided electrode members 111, 211 are faced with each other. The right-side divided electrode members 112, 212 are faced with each other.

The electric field applying electrode 100 composed of the divided electrode members 111, 112 corresponds to the first electrode row of the above-mentioned embodiments, while the grounding electrode 200 composed of the divided electrode members 211, 212 correspond to the second electrode row of the above-mentioned embodiments.

The left-side divided electrode member 111 of the electric field applying electrode 100 corresponds to, for example, the “first divided electrode member” as defined in claims, and the right-side divided electrode member 112 corresponds to the “second divided electrode member”. The electric field applying electrode 100 may be divided into three or more electrode members instead of two. In that case, selected one of those three divided electrode members serves as the first divided electrode member and another one of the remaining two, as the second divided electrode member, respectively.

A gap 33s is formed between the two kinds of electrodes 100, 200, i.e., first and second electrode rows. A processing gas coming from a processing gas source, not shown, is introduced into this gap 33s and plasmatized therein by electric field applied from the power source devices 301, 302. The processing gas thus plasmatized is sprayed onto the workpiece to achieve a desired plasma surface processing under generally normal pressure. The gap 33s serves as a processing gas path and a plasmatizing space.

Though not shown, the electric field applying electrode 100 and the ground electrode 200 are provided at least at one of the confronting surfaces thereof with a solid dielectric layer composed of ceramics such as alumina.

The two grounding divided electrode members 211, 212 are grounded through earth lines 3e, respectively.

The left-side first divided electrode member 111 is connected to the first power source device 301. The right side second divided electrode member 112 is connected to the second power source device 302 different from the first power source device 301. The power source devices 301, 302 each output a high frequency AD voltage, for example, in a pulse state or sine wave state.

In case the electric field applying electrode 100 is divided into three or more electrode members, it is desirous that the same number of power source devices as the number of the divided electrode members are employed and they are connected to each other in one-to-one relation. In that case, the power source device connected to the first divided electrode member of those three divided electrode members serves as the “first electrode device”, and the power source device connected to the second divided electrode member serves as the “second power source device”.

The first and second divided electrode members 111, 112 are not required to be arranged in a side-by-side relation in the same row but they may be arranged in different rows, respectively.

It is also accepted that the electric field applying electrode 100 is divided into a plurality of divided electrode members and the grounding electrode 200 is not divided and remained in a single unit. It is also accepted that the electric field applying electrode 100 is not divided and remained as a single unit, and a plurality of power source devices are connected to this single unit electric field applying electrode 100.

The electrode structure is not limited to the parallel flat plate-like structure but it may be a duplex annular structure. It may also be of such a structure that one has a circular cylindrical (roll-like configuration and the other has a circular cylindrical recessed surface.

The two power source devices 301, 302 are connected to a synchronizer 400. The synchronizer 400 synchronizes the output phases of the power source devices 301, 302.

According to the above-mentioned construction, since the divided electrode members 111, 112 are connected to the power source devices 301, 302, respectively, supply of power per unit area of the electrodes 100, 200 can sufficiently be increased even if the power source devices 301, 302 are not large in capacity. Accordingly, processing performance can be enhanced.

In addition, the two power source devices 301, 302 can be prevented from being deviated in phase by the synchronizer 400. Accordingly, a phase difference can be prevented from occurring between the divided electrode members 111, 112 and thus, an arc discharge can be prevented from occurring between those divided electrode members 111, 112. Owing to this arrangement, the interval between the divided electrode members 111, 112 can be reduced or the members 111, 112 can even be abutted with each other. Thus, processing irregularity can be prevented from occurring at a part corresponding to the space between the divided electrode members 111, 112. As a result, a favorable surface processing can be conducted.

Moreover, by dividing the electrodes 100, 200 into plural parts as in the first embodiment, etc., the respective electrode members can be reduced in length and bending caused by Coulomb force, dead weight, etc. can be reduced.

FIG. 45 shows a specific example of construction of FIG. 44. The first power source device 301 includes a first DC rectifier 311 connected to a commercial use AC power source A, a first inverter 321 connected to this first DC rectifier 311, and a first transformer 331 connected to the first inverter 321.

The DC rectifier 311 includes, for example, a diode bridge and a smooth circuit and is adapted to rectify the commercial use AD voltage of the commercial used power source A to DC.

The first inverter 321 includes a bridge circuit of first switching elements 321a, 321b, 321c, 321d composed of transistors, and switches and converts the DC after rectification to AC voltage having a predetermined wave form.

The secondary side of the first transformer 331 is connected to the first divided electrode member 111. The first transformer 331 increases the output voltage coming from the first inverter 321 and supplies it to the first divided electrode member 111.

The second power source device 302 has the same construction as the first power source device 301. That is, the second power source device 302 includes a second DC rectifier 312 connected to the commercial use AC power source A, a second inverter 322 connected to this second DC rectifier 321, and a second transformer 332 connected to the second inverter 322.

The second DC rectifier 312 includes, for example, a diode bridge, and a smooth circuit, and adapted to rectify the commercial use AC voltage of the commercial used power source A to DC.

The second inverter 322 includes a bridge circuit of the second switching elements 322a, 322b, 322c, 322d composed of transistors and switches and converts DC after flow rectification to AC voltage having a predetermined waveform.

The secondary side of the second transformer 332 is connected to the second divided electrode member 112. The second transformer 332 increases the output voltage coming from the second inverter 322 and supplies it to the second divided electrode member 112.

The synchronizer 400 comprises a control means for the first and second inverters 321, 322. That is, the synchronizer (inverter controller) 40 includes a common (single) gate signal output part 410 for the switching elements 321a through 321d, 322a through 322d of the two (plural) inverters 321, 322. The output part 410 is provided with four terminals 410a, 410b, 410c, 410d. A gate signal line 420a is extended from the terminal 410a. The gate signal line 420a is branched to two lines 421a, 422a. The branch line 421a is connected to a gate of the switching element 321a of the first power source device 301 through a pulse transformer 431a. The other branch line 422a is connected to a gate of the switching element 322a of the second power source device 302 through a pulse transformer 342a.

Similarly, a gate signal line 420b leading from the terminal 410b is branched to two branch lines. One of the branch lines, 421b, is connected to a gate of the switching element 321b of the first power source device 301 through a pulse transformer 431b and the other branch line 422b is connected to a gate of the switching element 322b of the second power source device 302 through a pulse transformer 432b.

A gate signal line 420c leading from the terminal 410c is branched to two branch lines. One of the branch lines, 421c, is connected to a gate of the switching element 321c of the first power source device 301 through a pulse transformer 431c and the other branch line 422c is connected to a gate of the switching element 322c of the second power source device 302 through a pulse transformer 432c.

A gate signal line 420d leading from the terminal 410d is branched to two branch lines. One of the branch lines, 421d, is connected to a gate of the switching element 321d of the first power source device 301 through a pulse transformer 431d, and the other branch line 422d is connected to a gate of the switching element 322d of the second power source device 302 through a pulse transformer 432d.

According to the above-mentioned construction, the gate signal can be distributed into the switching element 321a of the inverter 321 of the first power source device 301 and the switching element 322a of the second power source device 302 in parallel. Owing to this arrangement, the switching elements 321a, 322a can be turned on/off simultaneously. Similarly, the switching elements 321b, 322b can be turned on/off simultaneously, and the switching elements 321d, 322d can be turned on/off simultaneously.

Owing to the above-mentioned arrangement, the switching operation of the inverters 321, 322 of the two power source devices 301, 302 can reliably be synchronized, and the output phases of the power source devices 301, 302 can reliably be synchronized. Accordingly, a voltage having the same phase can be applied to the two divided electrode members 111, 112. Thus, a potential difference can reliably be prevented from occurring between the divided electrode members 111, 112 and an arc discharge can reliably be prevented from occurring. Owing to this arrangement, a stable and favorable plasma surface processing can reliably be conducted.

The inventor conducted plasma processing using the apparatus shown in FIG. 5. The switching frequency was 30 kHz, and the peak-to-peak voltage between the electrodes 10, 20 was Vpp=15 kV.

As a result, it was confirmed that any abnormal discharge such as arch discharge did not occur between the adjacent divided electrode members 111, 112.

FIG. 46 shows another specific example of construction of FIG. 44. This apparatus is different in construction of the synchronizer (inverter controller) from the apparatus of FIG. 45. That is, in the synchronizer 400, a gate signal output part is provided per each of the power source devices 301, 302. That is, the synchronizer 400 is provided with a first gate signal output part 411 for the first power source device 301 and a second gate signal output part 412 for the second power source device 302, and those gate signal output parts 411, 412 are synchronously controlled by a common synchronization signal supply part 450.

The first gate signal output part 411 is provided with four terminals 411a, 411b, 411c, 411d. A gate signal line 421a is extended from the terminal 411a. The gate signal line 421a is connected to a gate of the switching element 321a of the first power source device 301 through a pulse transformer 431a. Similarly, a gate signal line 421b is extended from the terminal 411b and connected to a gate of the switching element 321b through a pulse transformer 431b. A gate signal line 421c is extended from the terminal 411c and connected to a gate of the switching element 321c through a pulse transformer 431c. A gate signal line 421d is extended from the terminal 411d and connected to a gate of the switching element 321d through a pulse transformer 431d.

The second gate output part 412 is provided with four terminal 412a, 412b, 412c, 412d. A gate signal line 422a is extended from the terminal 412a. The gate signal line 422a is connected to a gate of the switching element 322a of the second power source device 302 through a pulse transformer 432a. Similarly, a gate signal line 422b is extended from the terminal 412b and connected to a gate of the switching element 322b through a pulse transformer 412b. A gate signal line 422c is extended from the terminal 412c and connected to a gate of the switching element 322c through a pulse transformer 432c. A gate signal line 422d is extended from the terminal 412d and connected to a gate of the switching element 322d through a pulse transformer 432d.

The synchronization signal supply part 450 supplies a common synchronization signal to the two gate signal output parts 411, 412. That is, a synchronization signal line 460 is extended from the output terminal of the synchronization signal supply part 450. The synchronization signal line 460 is branched to two lines 461, 462. One of the branch lines, 461, is connected to the first gate signal output part 411 and the other branch line 462 is connected to the second gate signal output part 412.

According to the above-mentioned construction, the synchronization signal coming from the synchronization signal supply part 450 is distributed into the two gate signal output parts 411, 412 in parallel, and based on this synchronization signal, the gate signal output parts 411, 412 output gate signals, respectively. Owing to this arrangement, the switching operation of the two power source devices 301, 302 can reliably be synchronized with each other and the output phases of the power source devices 301, 302 can reliably be synchronized. Thus, voltage having the same phase can be applied to the two divided electrode members 111, 112, and an arc discharge can reliably be prevented from occurring which would otherwise occur due to potential difference generated between the divided electrode members 111, 112. Owing to this arrangement, a stable and favorable plasma surface processing can reliably be conducted.

FIG. 47 shows a modified embodiment of FIG. 46. A synchronizer of this modified embodiment is provided with a first control IC 413 for the first power source device 301 and a second control IC 414 for the second power source device 302. The first control IC 413 includes a function corresponds to the synchronization signal supply part 450 and first gate signal output part 411 of FIG. 46. That is, the first control IC 413 has an oscillation circuit built therein and based on oscillation signal outputted from this oscillation circuit, gate signals are outputted to the first inverter 321 from the terminals 411a, 411b, 411c, 411d. Moreover, the oscillation circuit of the first control IC 413 is connected to the second control IC 414 through an oscillation signal line 463. Owing to this arrangement, the oscillation signal outputted from the first control IC 413 is also inputted into the second control IC 414.

The second control IC 414 includes a function corresponding to the second gate signal output part 412 of FIG. 46 and outputs gate signals from the terminals 412a, 412b, 412c, 412d to the second inverter 322 based on the oscillation signal coming from the first control IC 413.

Owing to the above-mentioned arrangement, the switching operation of the two inverters 321, 322 can reliably be synchronized, and the output phases of the power source devices 301, 302 can reliably be synchronized.

FIG. 48 shows another modified embodiment of FIG. 46.

A first LC resonance circuit 315 is constituted by the first divided electrode members 111, 211 and a secondary coil of the first transformer 331, and a second LC resonance circuit 352 is constituted by the second divided electrode members 112, 212 and a secondary coil of the second transformer 332. As the power source devices 301, 302, a resonance type high frequency power source for resonating those LC resonance circuits 351, 352 is used.

A feedback signal line 459 is extended from the output side (primary side of the transformer 331) of the inverter 321 of the first power source device 301. This feedback signal line 459 is connected to a detection circuit 452 stored in the synchronizer 400. The detection circuit 452 is connected to a correction circuit 453 stored in the synchronization signal supply part 450.

The detection circuit 452 detects an output current (primary current of the first transformer 331) of the first inverter 321 through the feedback signal line 459 and outputs it to the correction circuit 453. The correction circuit 453 corrects the oscillation frequency based on the input from the detection circuit 452. That is, when the output frequency of the inverter 321 is lower than the resonance frequency of the first LC resonance circuit 351, the oscillation frequency is increased. On the other hand, when the output frequency of the first inverter 321 is higher than the resonance frequency of the first LC resonance circuit 351, the oscillation frequency is lowered. The synchronization signal supply part 450 distributes the synchronization signal of an oscillation frequency after correction into the first gate signal output part 411 and the second gate signal output part 412 in parallel. Owing to this arrangement, the two power source devices 301, 302 can be synchronized and in addition, the output frequency of the inverters 321, 322 of the power source devices 301. 302 can reliably be made coincident with the resonance frequency of the LC resonance circuits 351, 352, and high output can be obtained.

The sizes and thus, the electrostatic capacities of the first and second electrode members are preferably same as in the embodiments of FIGS. 44 through 48 but they may be different. For example, in an apparatus shown in FIG. 49(a), the first divided electrode members 111, 211 are larger in lengthwise dimension and thus, larger in electrostatic capacity than the second divided electrode members 112, 212. In that case, as shown in FIG. 49(b), the rising and/or falling time of the output pulse voltage to the second divided electrode member 112 from the second power source device 302 is preferably longer than the rising/falling time of the output pulse voltage to the first divided electrode member 111 from the first power source device 301. In the alternative, as shown in FIG. 50, a condenser 113 may be connected to the divided electrode member 112 which is smaller in size. Owing to this arrangement, the waveforms of voltage applied to the large-sized divided electrode member 111 and the small-sized divided electrode member 112 can be made coincident with each other.

The present invention is not limited to the above-mentioned embodiments but many changes and modifications can be made without departing from the spirit of the invention.

For example, in the electrode structure, the adjacent row-to-row partial gaps 33p may be isolated from each other by filling a partition wall such as an insulating resin between the communication space 33r formed between the adjacent row-to-row partial gaps 33p.

Multi-stages of electrode units 30X may be arranged in the back and forth directions.

It is also accepted that the size of the in-row gap 33q may be properly adjusted so as to serve as a processing gas path by adjusting the dimension and arrangement position in the back and forth directions.

The width of the in-row gap 33q and the width of the row-to-row partial gap 33p are properly established. The width of the in-row gap 33q may be larger or smaller than that of the row-to-row partial gap 33p.

The essential parts of the various embodiments may be combined such as, for example, the gas guide or gas introduction means in the gas introduction port forming part 43 of FIGS. 9 through 16 and 31 through 32, as well as elsewhere, the gas guide in the discharge space 33s of FIGS. 4 through 8, as well as elsewhere, and the gas guide in the jet port forming part 49 of FIGS. 20 through 30, as well as elsewhere.

The processing gas introduction part 20 may be eliminated and the processing gas may be directly introduced into the discharge processing part 30 from the processing gas source. It is also accepted that a pressure adjusting valve for preventing pressure change is disposed on the way.

The present invention can evenly be applied to various plasma surface processing such as cleaning, film deposition, etching, surface modification (hydrophilic processing, water repellent processing, etc.) and ashing, it can also be applied to plasma surface processing using not only glow discharge but also corona discharge, surface discharge, arc discharge and the like, and it can also be applied to plasma surface processing conducted not only under generally normal pressure but also under reduced pressure.

### BRIEF DESCRIPTION OF DRAWINGS

[FIG. 1]

FIG. 1 is a side sectional view showing a remote type normal pressure plasma processing apparatus according to a first embodiment.

[FIG. 2]

FIG. 2 is a plan sectional view of the remote type normal pressure plasma processing apparatus taken on line II-II of FIG. 1.

[FIG. 3]

FIG. 3 is a plan view in which an electrode structure is projected onto a glass substrate as a workpiece of the remote type normal pressure plasma processing apparatus.

[FIG. 4]

FIG. 4 is a schematic plan view showing an embodiment in which a gas guiding member is disposed in a row-to-row gap of electrodes of an electrode structure.

[FIG. 5]

FIG. 5 is a front sectional view of the electrode structure taken on line V-V of FIG. 4.

[FIG. 6]

FIG. 6 is a front sectional view showing a modified embodiment of a gas guiding member.

[FIG. 7]

FIG. 7 is a front sectional view showing a modified embodiment of the gas guiding member.

[FIG. 8]

FIG. 8 is a front sectional view showing a modified embodiment of the gas guiding member.

[FIG. 9]

FIG. 9 is a front view showing an embodiment in which a processing gas introduction port forming part is provided with a gas guide.

[FIG. 10]

FIG. 10 is a front view showing another embodiment of the gas guide disposed at a processing gas introduction port forming part.

[FIG. 11]

FIG. 11 is a plan view showing an embodiment in which an end face of each electrode member is slanted in match with the slantwise flow of processing gas.

[FIG. 12]

FIG. 12 is a side sectional view taken on line XII-XII of FIG. 13, showing another embodiment of the gas guide disposed at a processing gas introduction port forming part.

[FIG. 13]

FIG. 13 is a front sectional view taken on line XIII-XIII of FIG. 12.

[FIG. 14]

FIG. 14 is a perspective view of a flow rectification member as the gas guide of FIG. 12.

[FIG. 15]

FIG. 15 is a front sectional view showing an embodiment in which a processing gas introduction port forming part is provided with a blocking member as the gas guide for closing the boundary between the row-to-row partial gaps.

[FIG. 16]

FIG. 16 is a plan sectional view of the embodiment of FIG. 15.

[FIG. 17]

FIG. 17 is a front sectional view showing an embodiment in which a gate type spacer serving as the gas guide is disposed between the electrodes.

[FIG. 18]

FIG. 18 is a view in which the gate-type spacer is viewed square.

[FIG. 19]

FIG. 19 is a front sectional view of the embodiment of FIG. 17.

[FIG. 20]

FIG. 20 is an exploded perspective view showing an embodiment in which a jet port forming part is provided with a gas guide.

[FIG. 21]

FIG. 21 is a front view of the embodiment of FIG. 20.

[FIG. 22]

FIG. 22 is an exploded perspective view showing an embodiment in which the jet port is provided with a porous plate as the gas guide.

[FIG. 23]

FIG. 23 is a front sectional view of the embodiment of FIG. 22.

[FIG. 24]

FIG. 24 is an exploded perspective view showing an embodiment in which the jet port forming part is provided with a blocking part as the gas guide for closing the boundary between the row-to-row partial gaps.

[FIG. 25]

FIG. 25 is a side view taken on line XXV-XXV of FIG. 24.

[FIG. 26]

FIG. 26 is a front view taken on line XXVI-XXVI of FIG. 24.

[FIG. 27]

FIG. 27 is an exploded perspective view showing an embodiment in which the downstream end of the in-row gap is open through an in-row jet port.

[FIG. 28]

FIG. 28 is a plan view of the jet port forming member (lower plate) of the embodiment of FIG. 27.

[FIG. 29]

FIG. 29 is a plan view showing a modified embodiment of the in-row jet port.

[FIG. 30(a)]

FIG. 30(a) is a plan view showing another modified embodiment of the in-row jet port.

[FIG. 30(b)]

FIG. 30(b) is a plan view showing another modified embodiment of the in-row jet port.

[FIG. 31]

FIG. 31 is an exploded perspective view showing an embodiment in which a processing gas introduction part is provided with an in-row introduction port.

[FIG. 32]

FIG. 32 is a plan view showing the processing gas instruction part of FIG. 31.

[FIG. 33]

FIG. 33 is a plan view showing an embodiment in which the mutually opposing electrode members of the first and second electrode rows are slightly deviated.

[FIG. 34]

FIG. 34 is a plan sectional view showing an embodiment in which the in-row gap is slanted.

[FIG. 35]

FIG. 35 is an exploded perspective view of the embodiment of FIG. 34.

[FIG. 36]

FIG. 36(a) is a plan view showing an intersecting part between a row-to-row gap and an inclination in-row gap on an enlarged basis, and (b) and (c) show enlarged plan views, respectively showing modified examples in which the inclination angle between the inclination in-row gap is varied.

[FIG. 37]

FIG. 37 is a plan sectional view showing an embodiment in which the in-row gap is slanted and the electrode members of each electrode row is four.

[FIG. 38]

FIG. 38 is an exploded perspective view of the embodiment of FIG. 37.

[FIG. 39]

FIG. 39 is a plan view showing an embodiment in which a common (single) power source is used.

[FIG. 40]

FIG. 40 is a plan view showing an embodiment in which each electrode row has the same polarity.

[FIG. 41]

FIG. 41 is a plan view showing an embodiment in which each electrode has the same polarity and a common (single) power source is used.

[FIG. 42]

FIG. 42 is a plan sectional view of an embodiment in which the end faces of the adjacent electrode members of each electrode row are abutted with each other so that the in-row gap is eliminated.

[FIG. 43]

FIG. 43 is a plan sectional view of an embodiment in which each row has the same polarity in FIG. 42.

[FIG. 44]

FIG. 44 is a circuit diagram showing a basic construction of an embodiment provided with a synchronizer for synchronizing a plurality of power source devices.

[FIG. 45]

FIG. 45 is a circuit diagram showing an embodiment which has a specific construction of FIG. 44.

[FIG. 46]

FIG. 46 is a circuit diagram showing another embodiment of the specific construction of FIG. 44.

[FIG. 47]

FIG. 47 is a circuit diagram showing a modified embodiment of FIG. 46.

[FIG. 48]

FIG. 48 is a circuit diagram showing another modified embodiment of FIG. 46.

[FIG. 49(a)]

FIG. 49(a) is a circuit diagram showing an embodiment in which the first and second divided electrode members are different in size in FIG. 44.

[FIG. 49(b)]

FIG. 49(b) is a graph showing the waveforms of output voltage of the first and second power source devices of FIG. 49(a), wherein the horizontal axis shows time and the vertical axis shows voltage.

[FIG. 50]

FIG. 50 is a circuit diagram showing an embodiment in which another solving means is applied to FIG. 49(a).

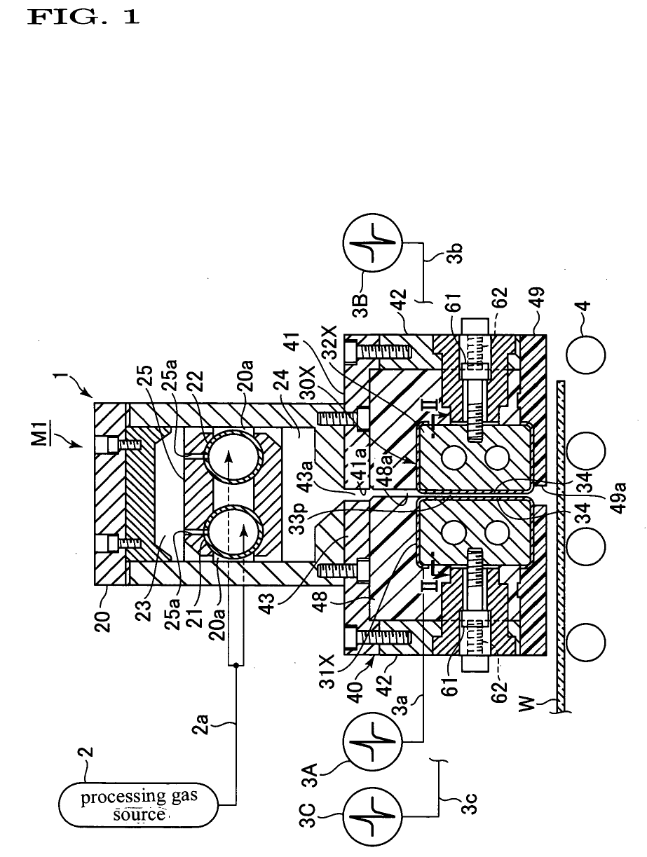

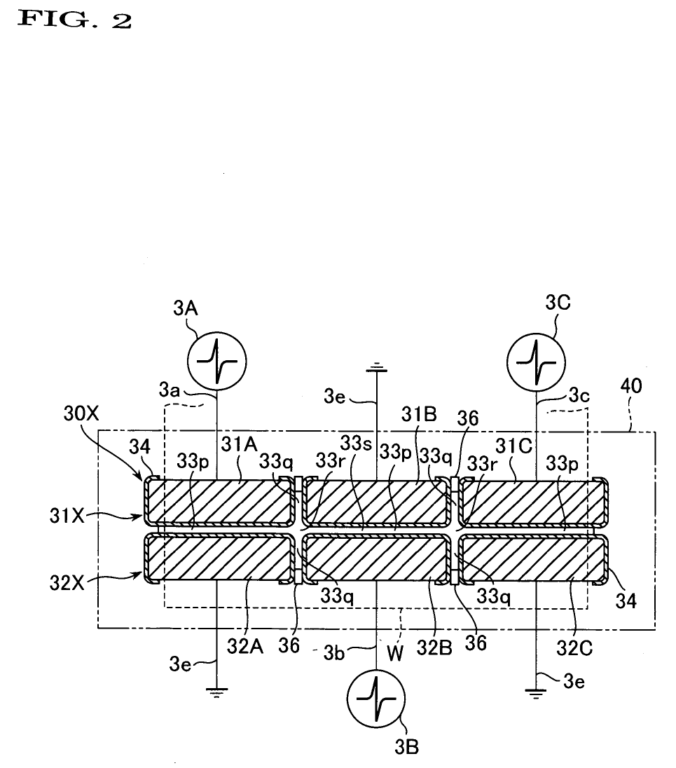

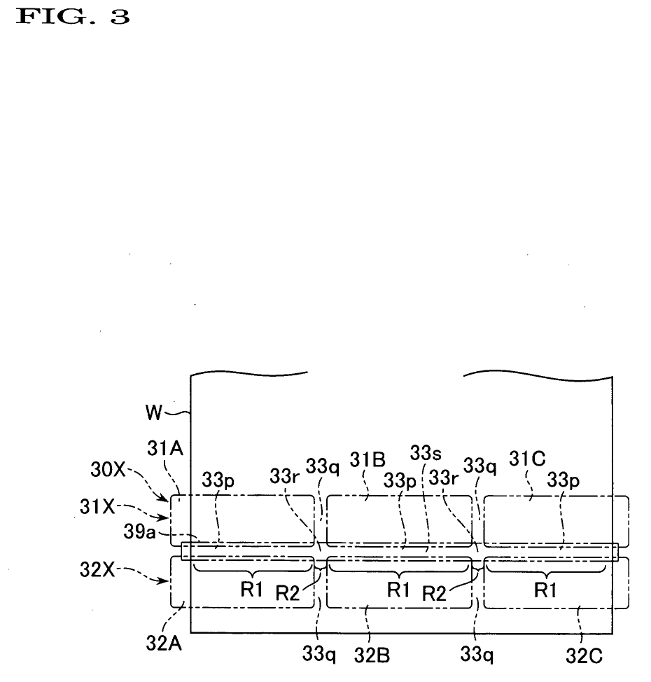

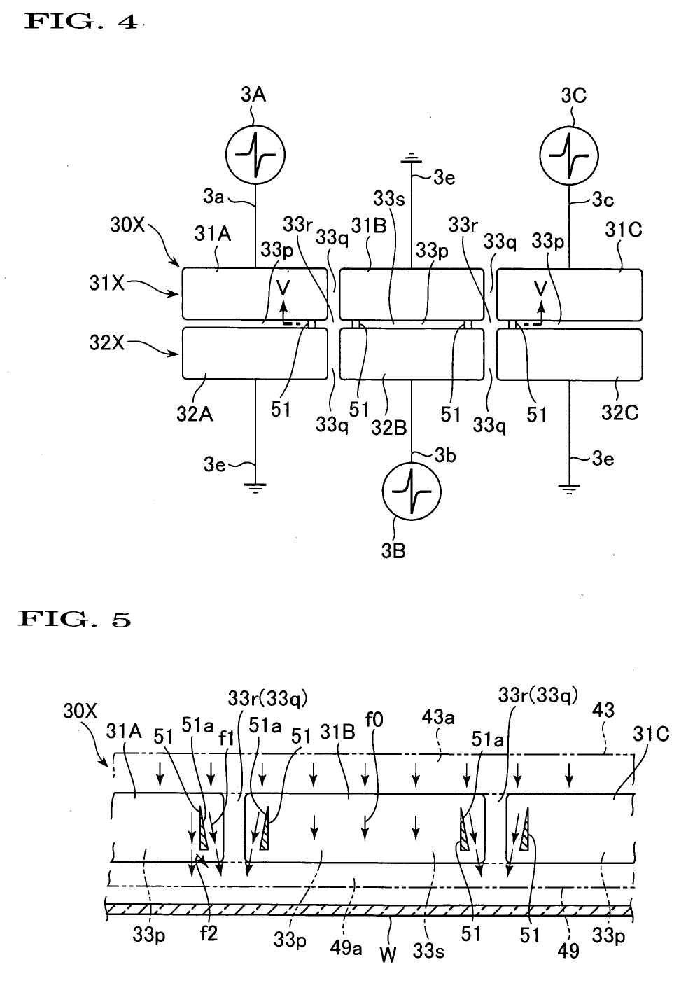

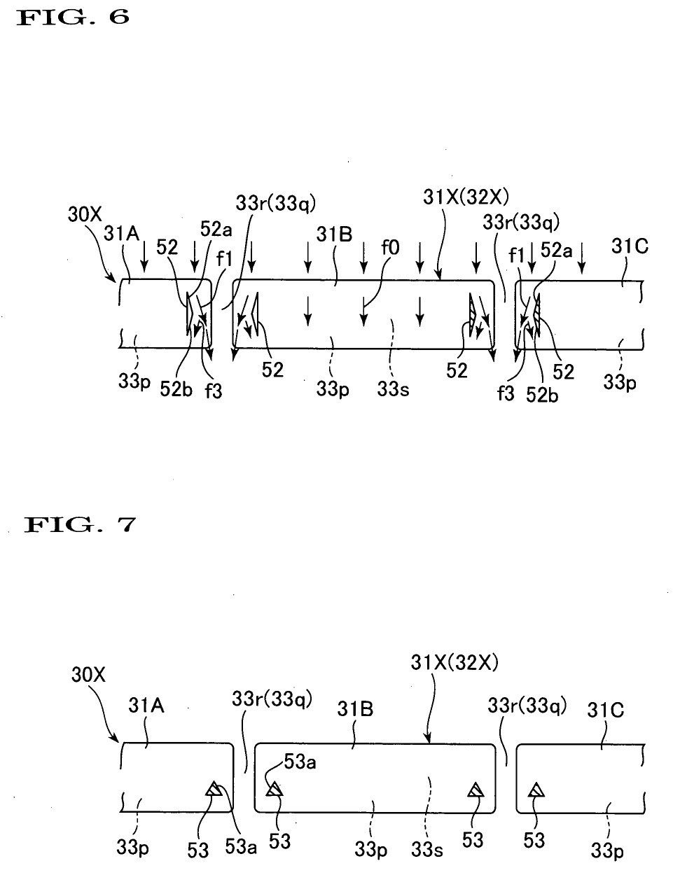

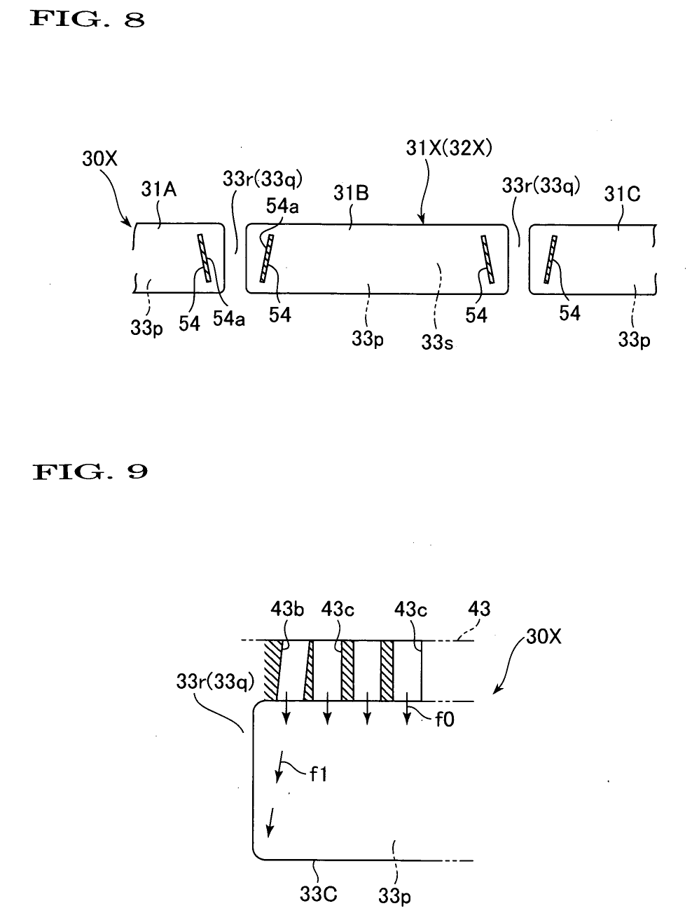

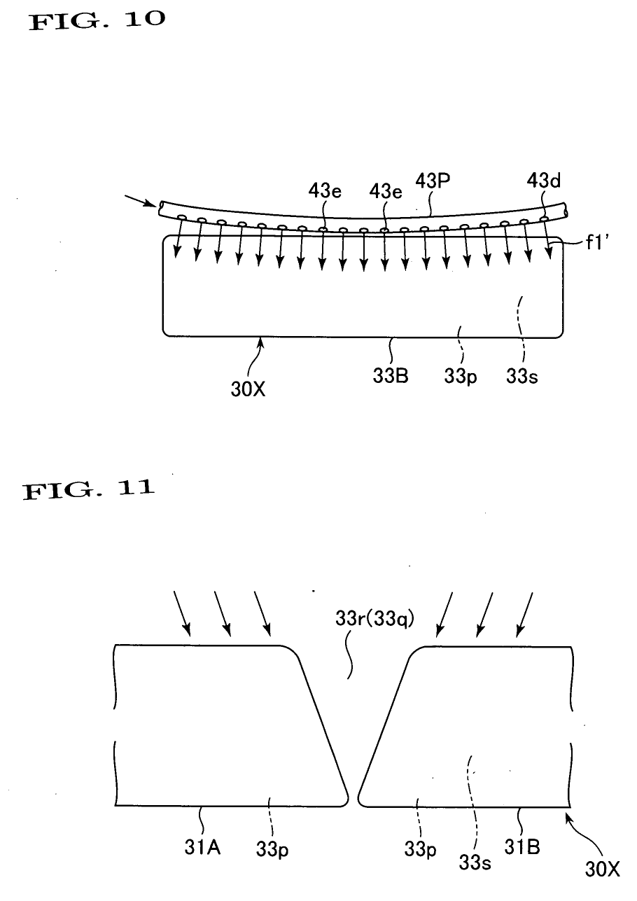

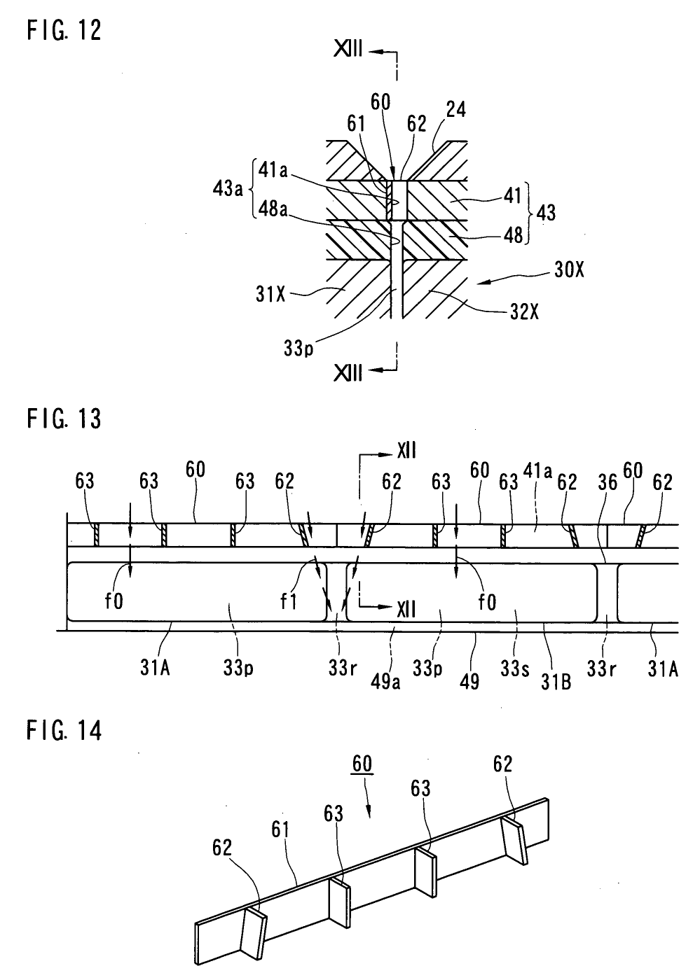

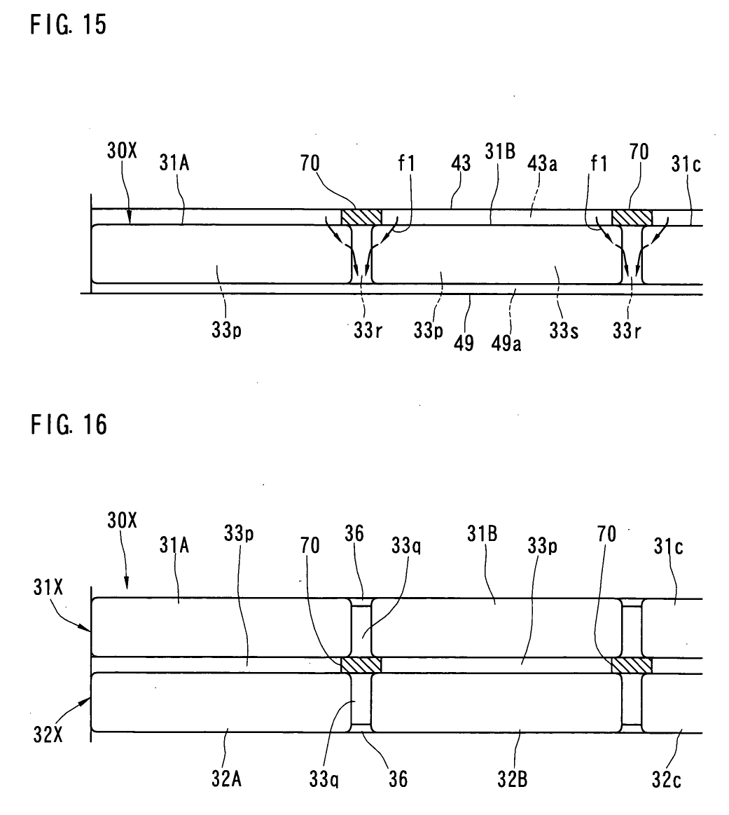

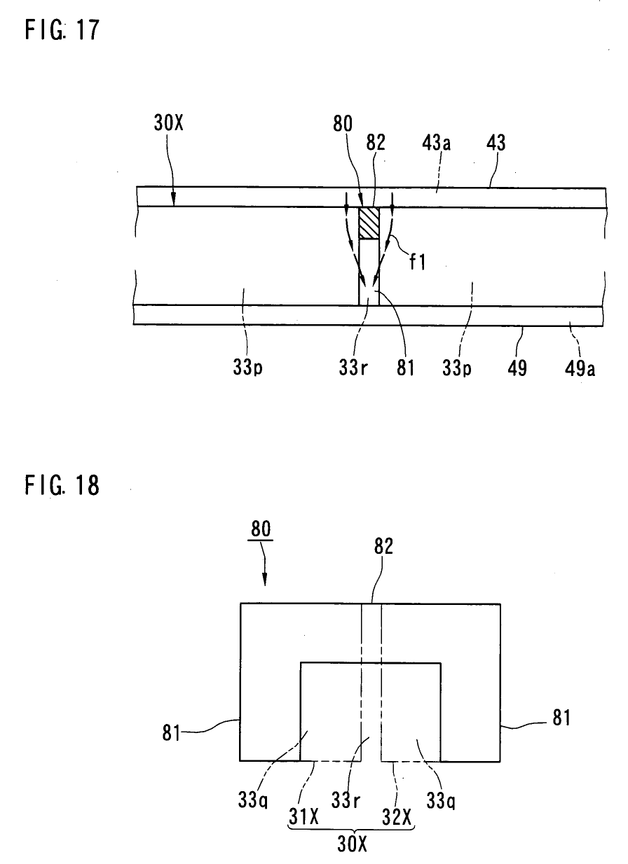

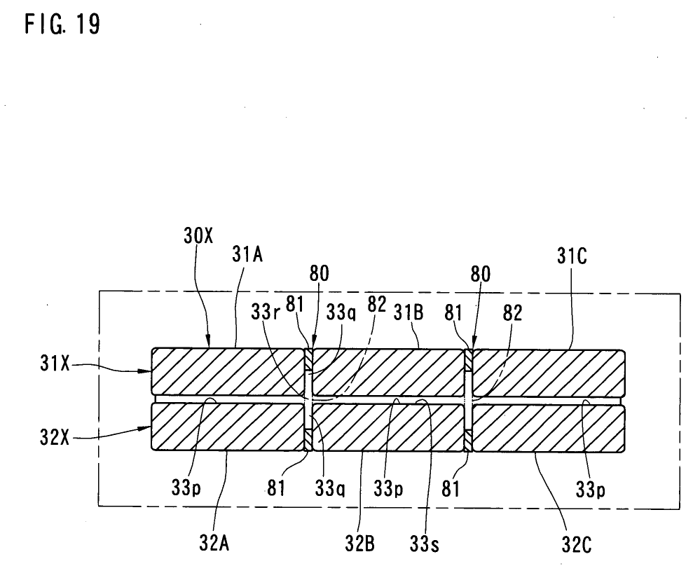

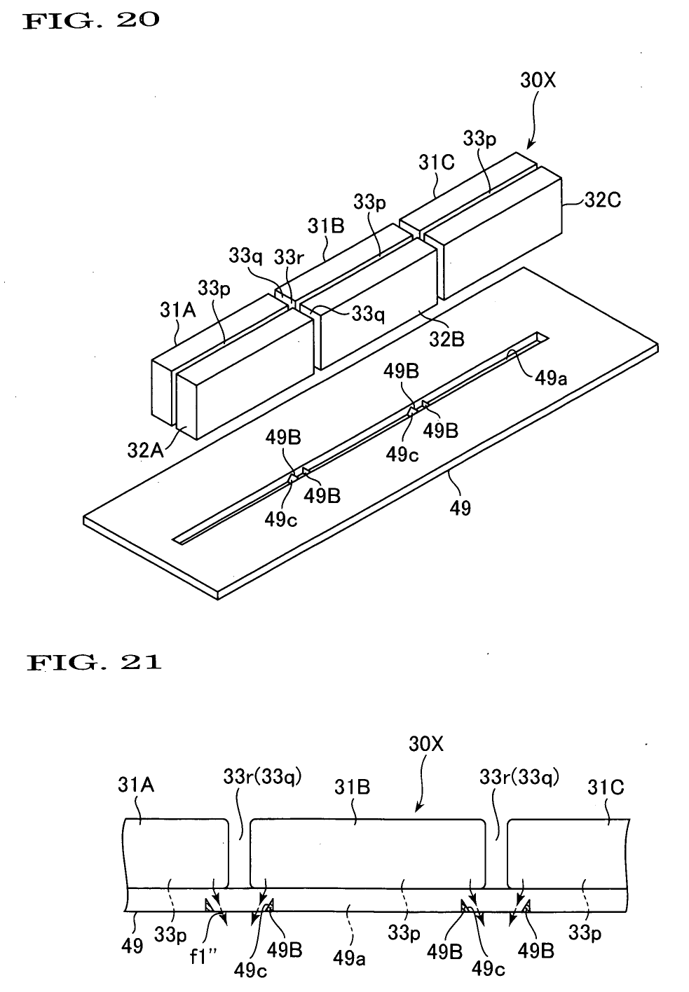

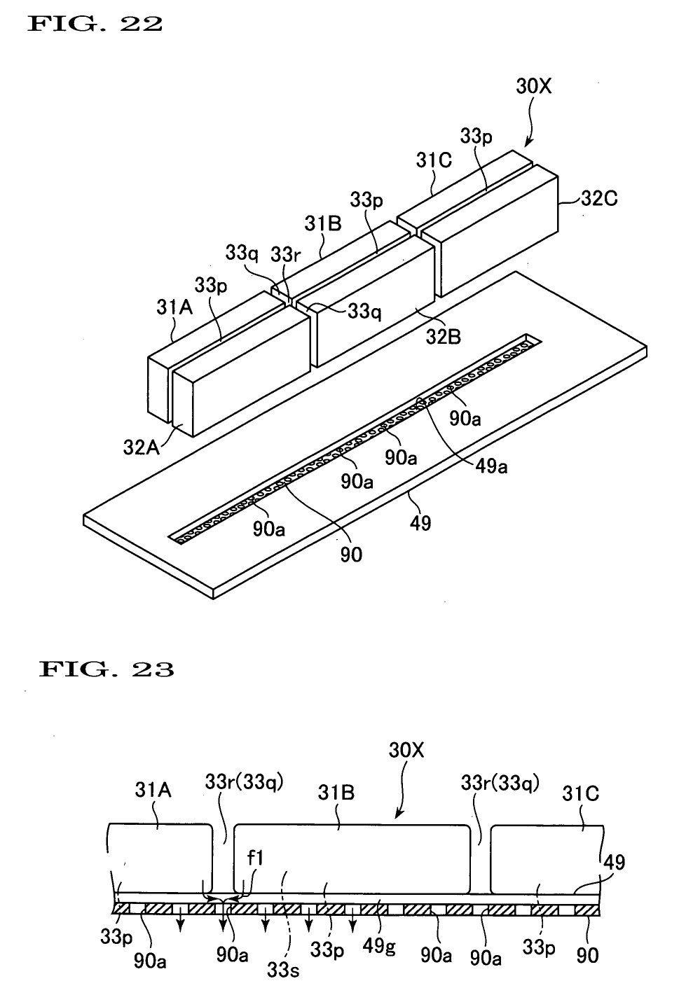

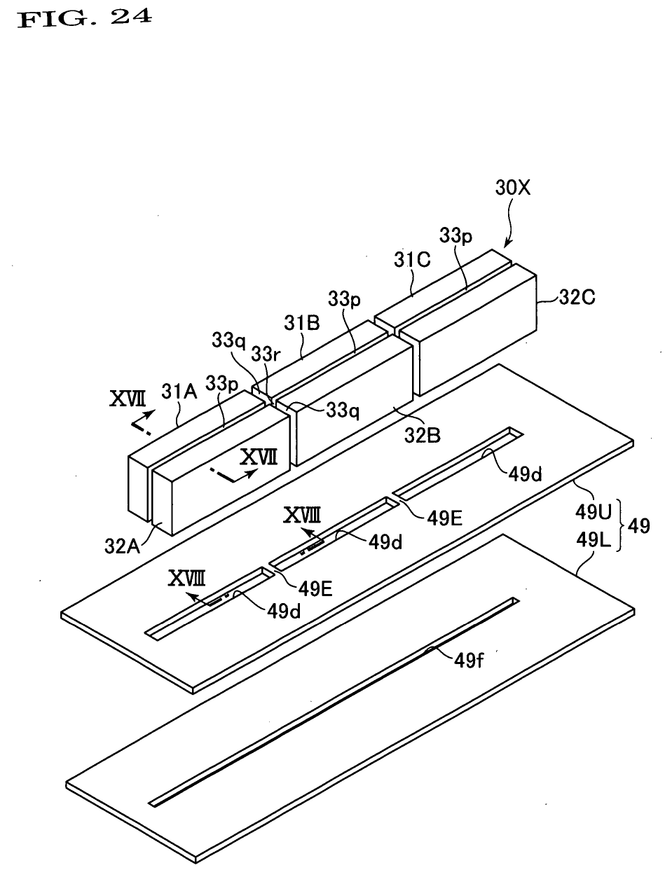

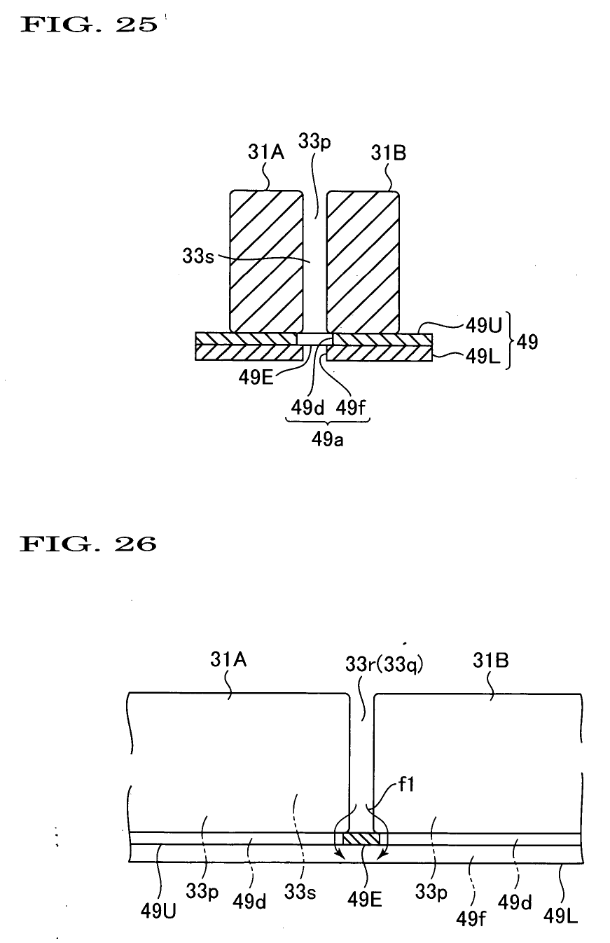

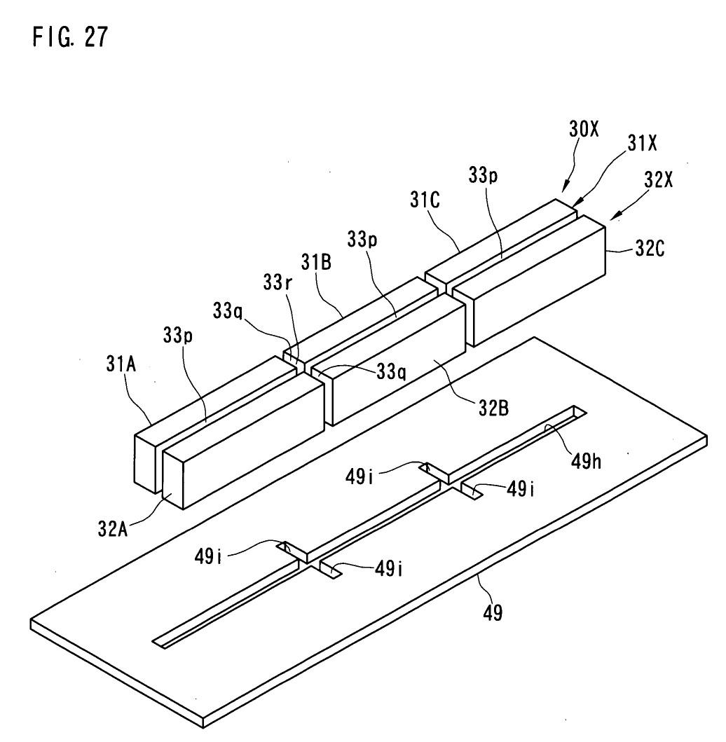

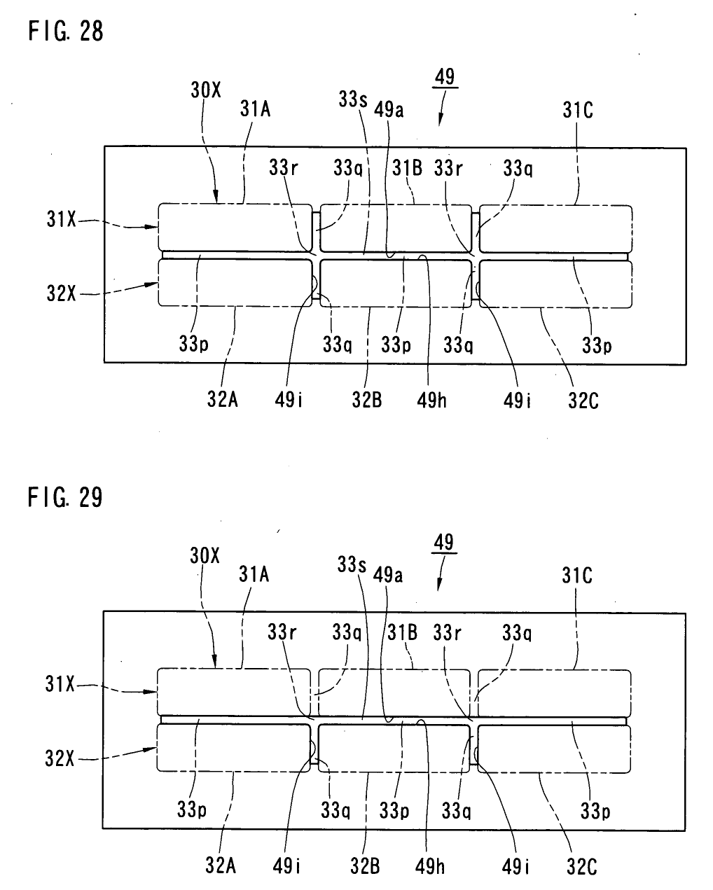

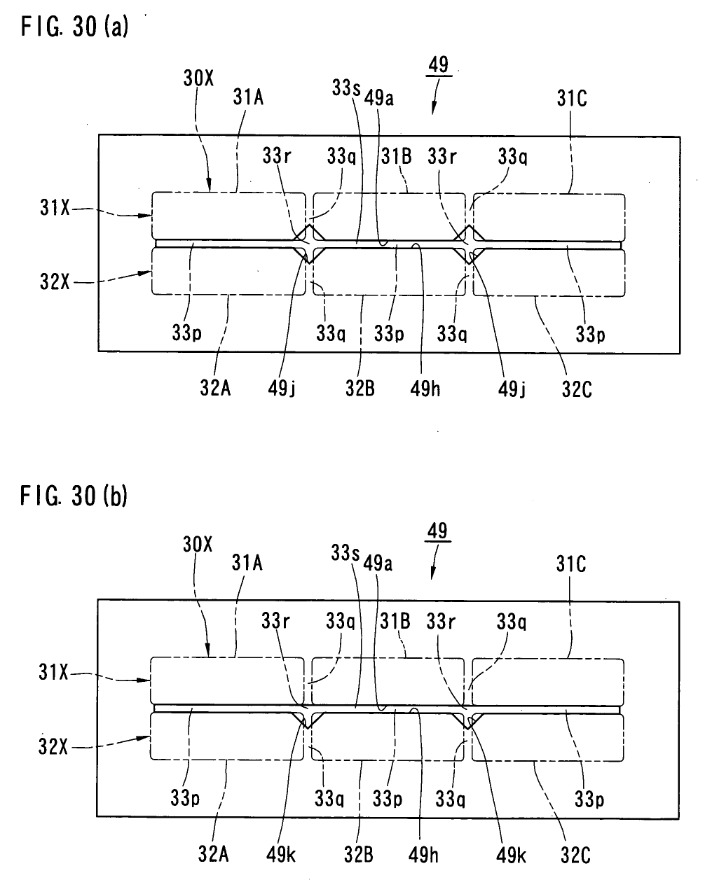

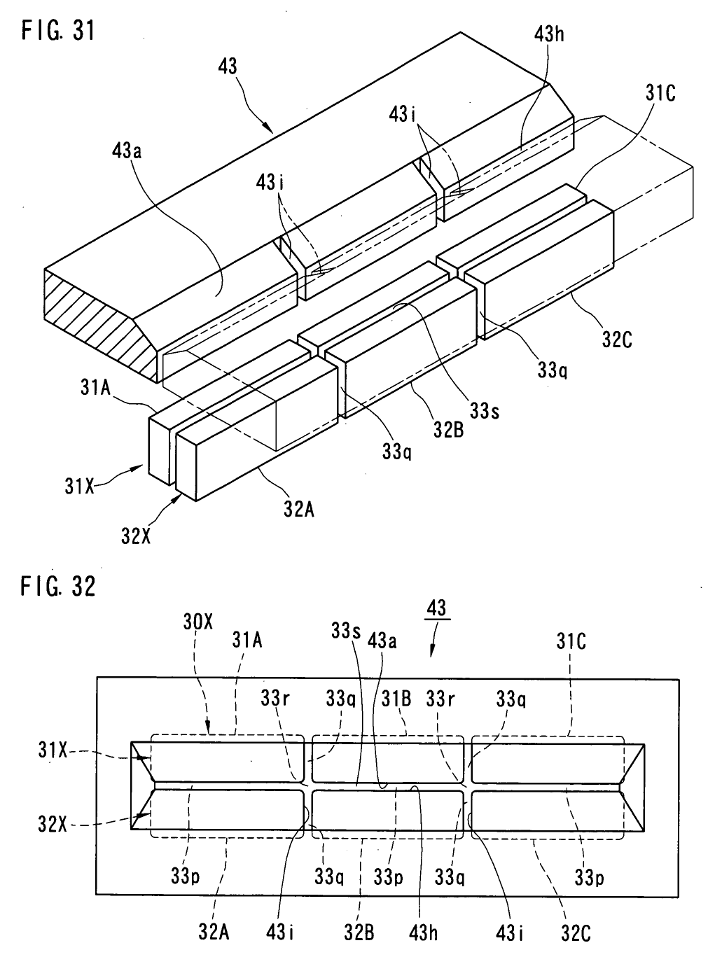

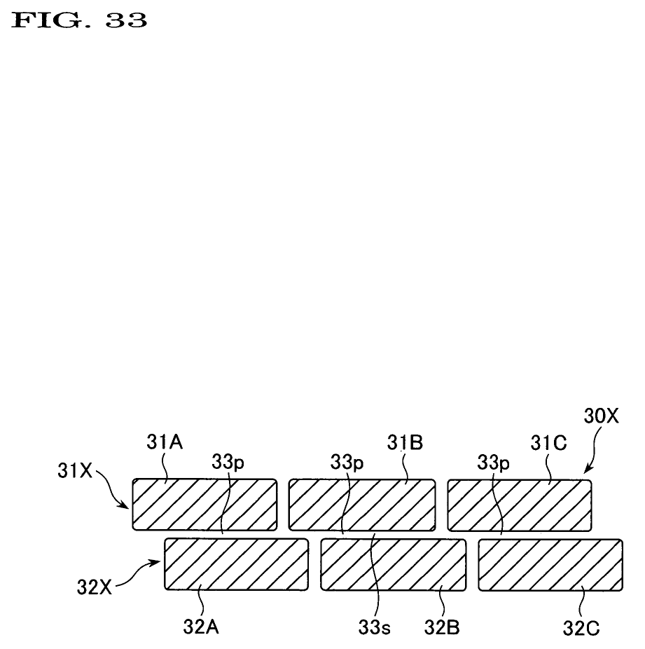

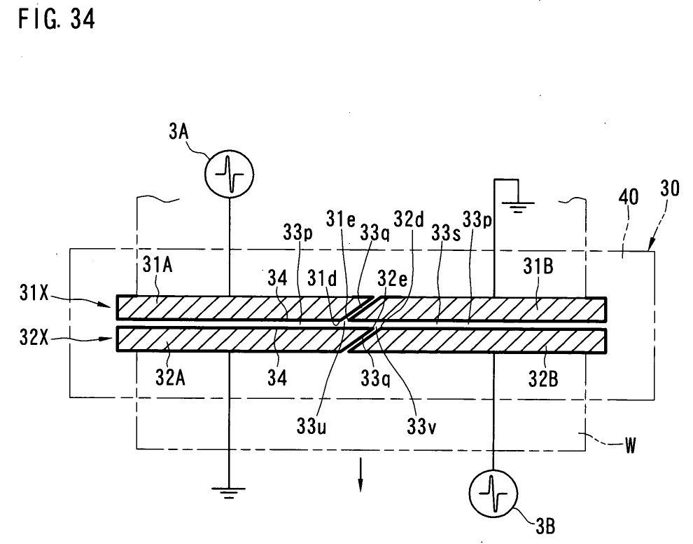

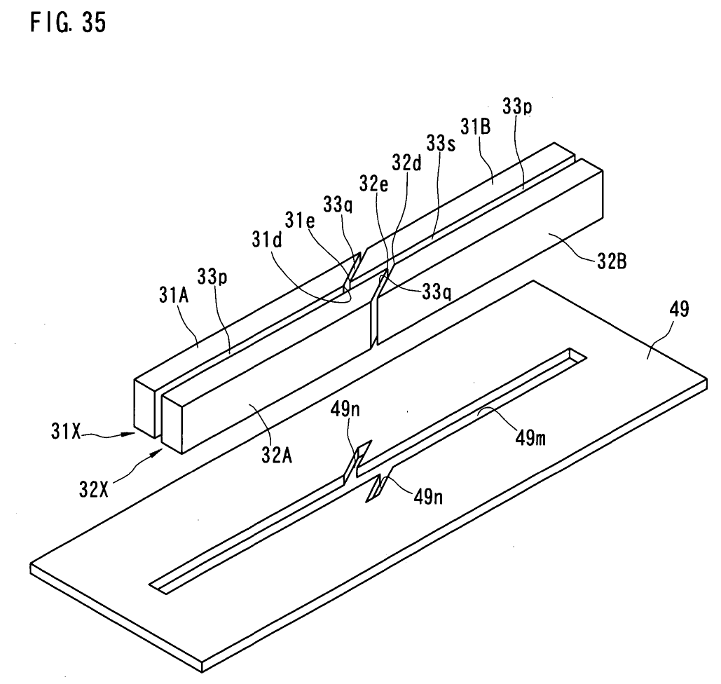

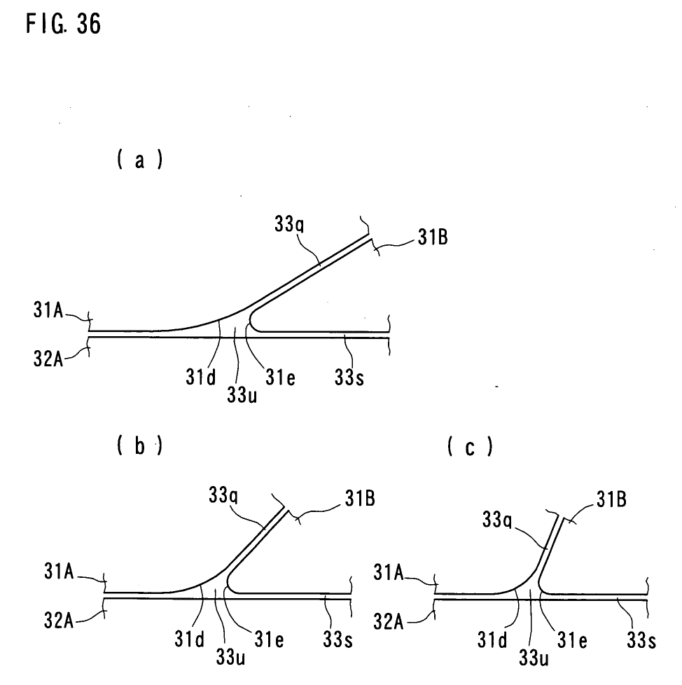

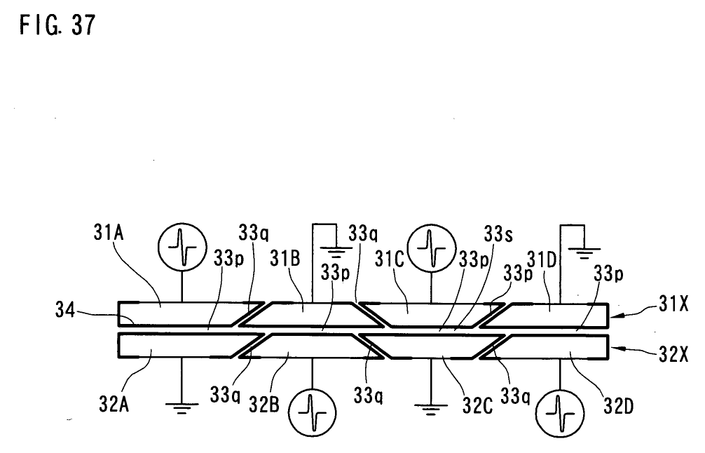

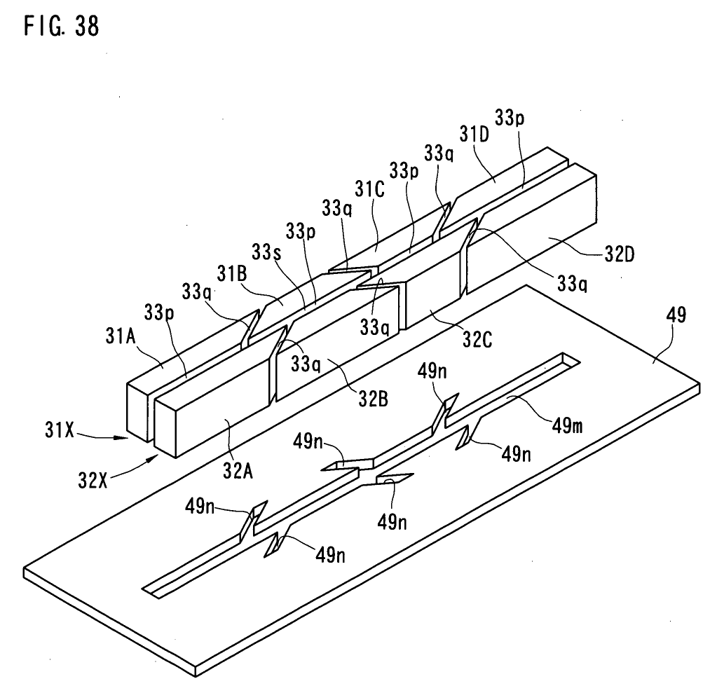

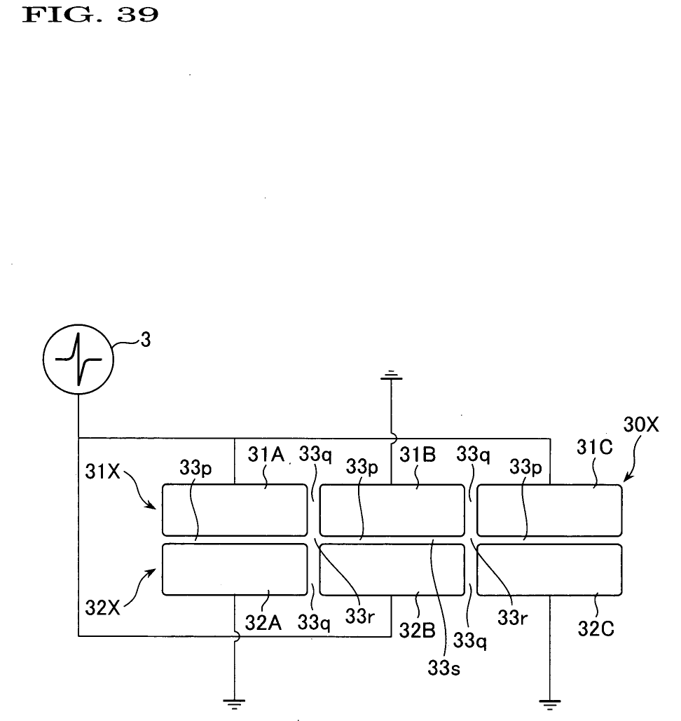

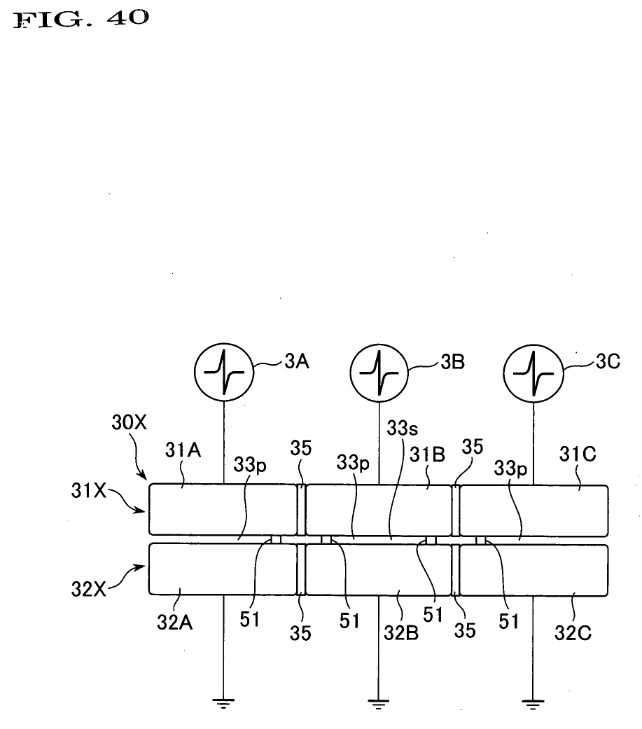

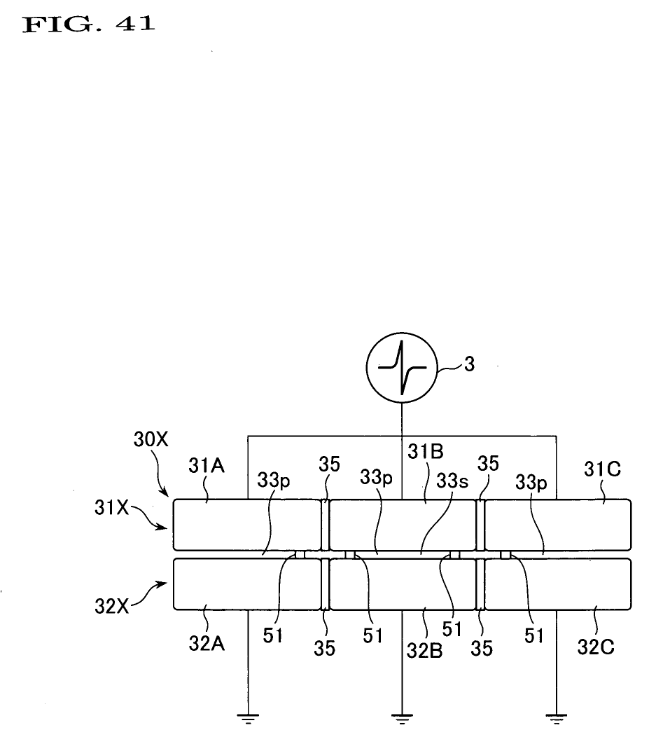

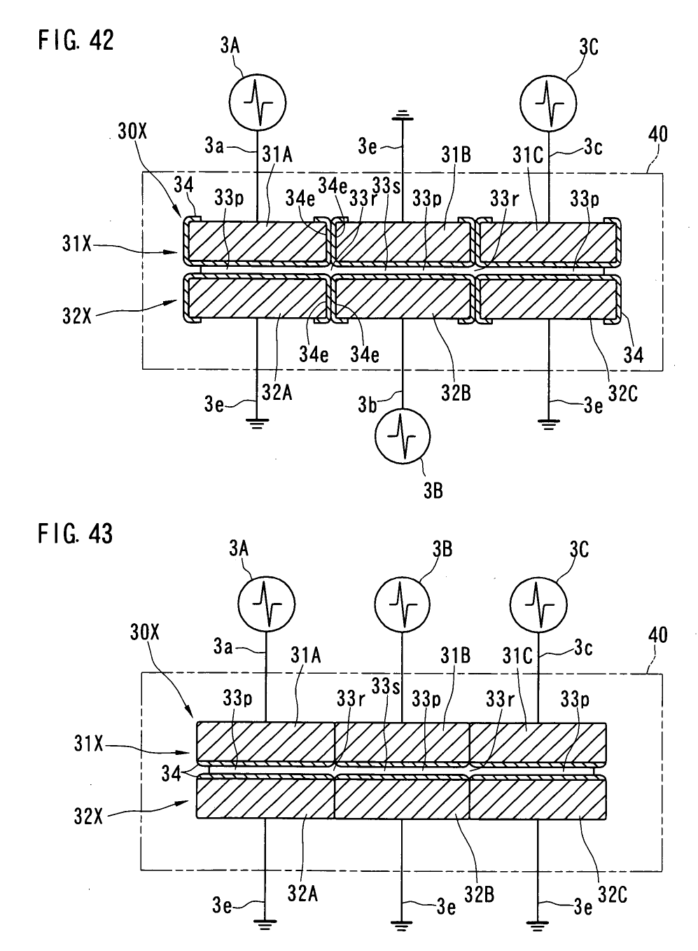

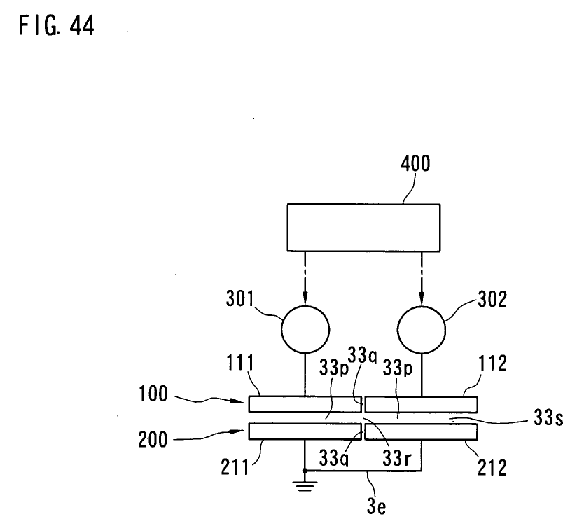

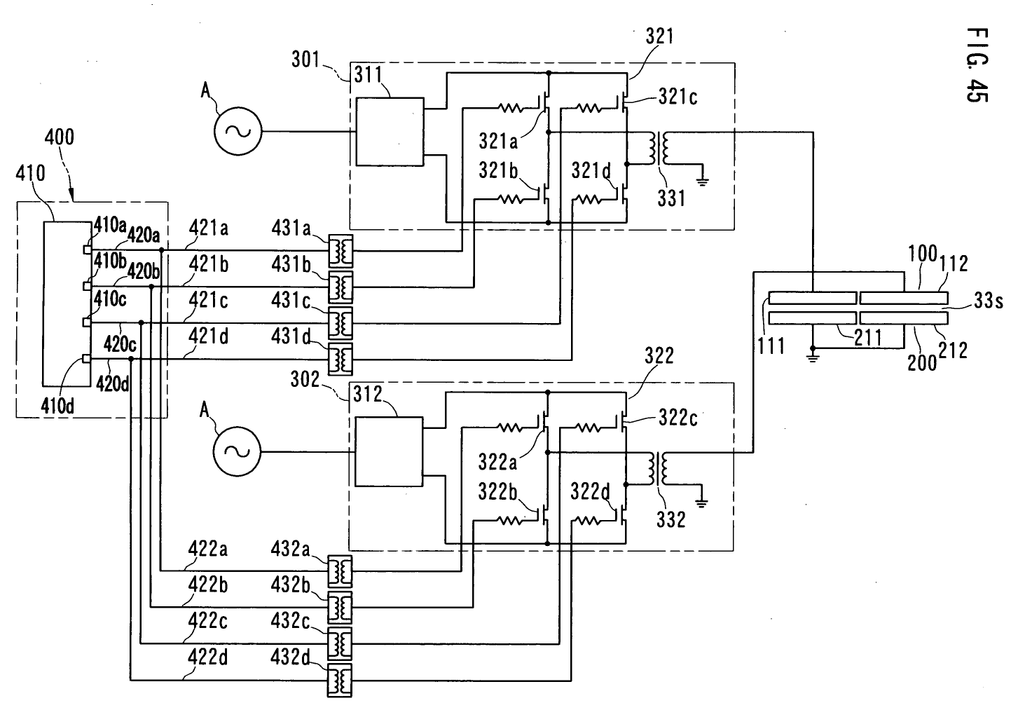

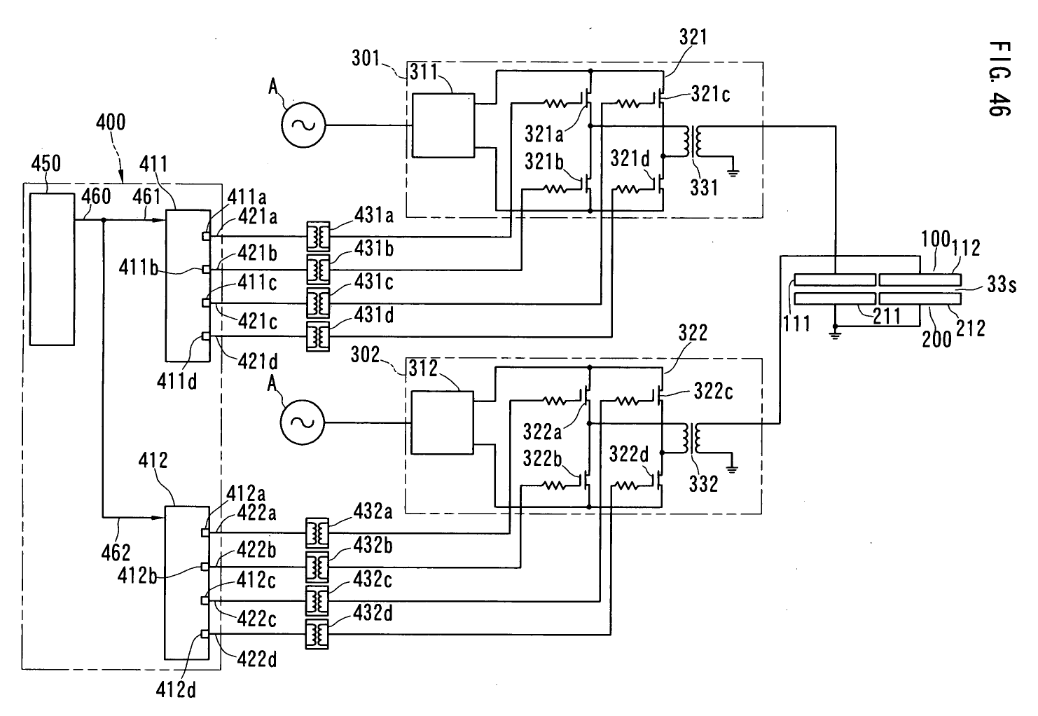

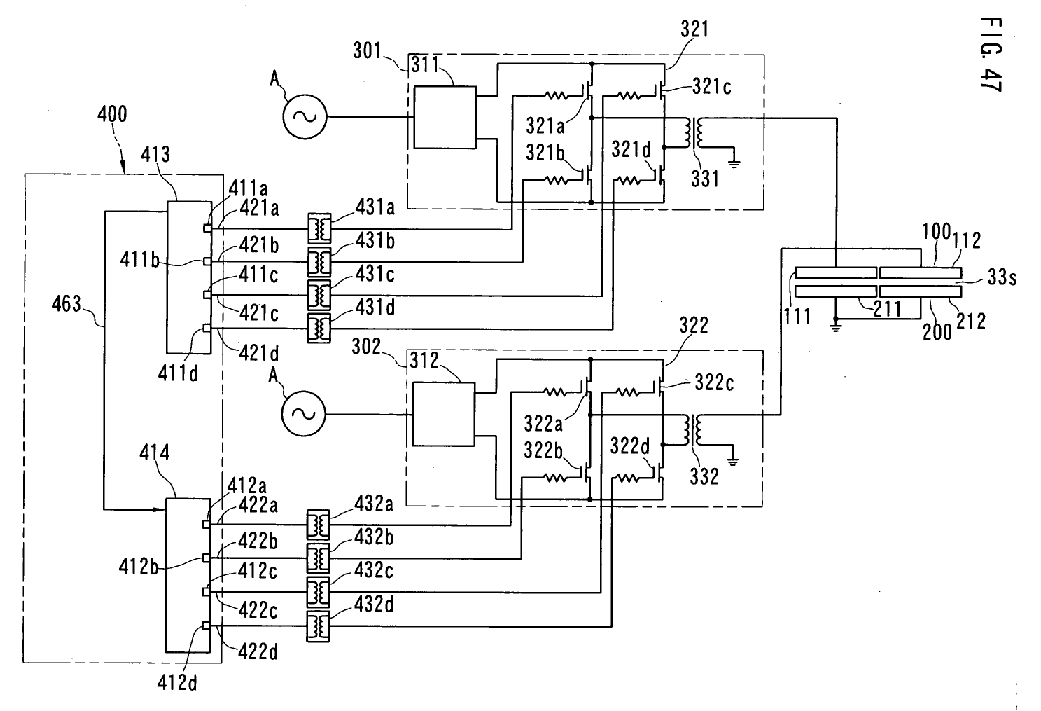

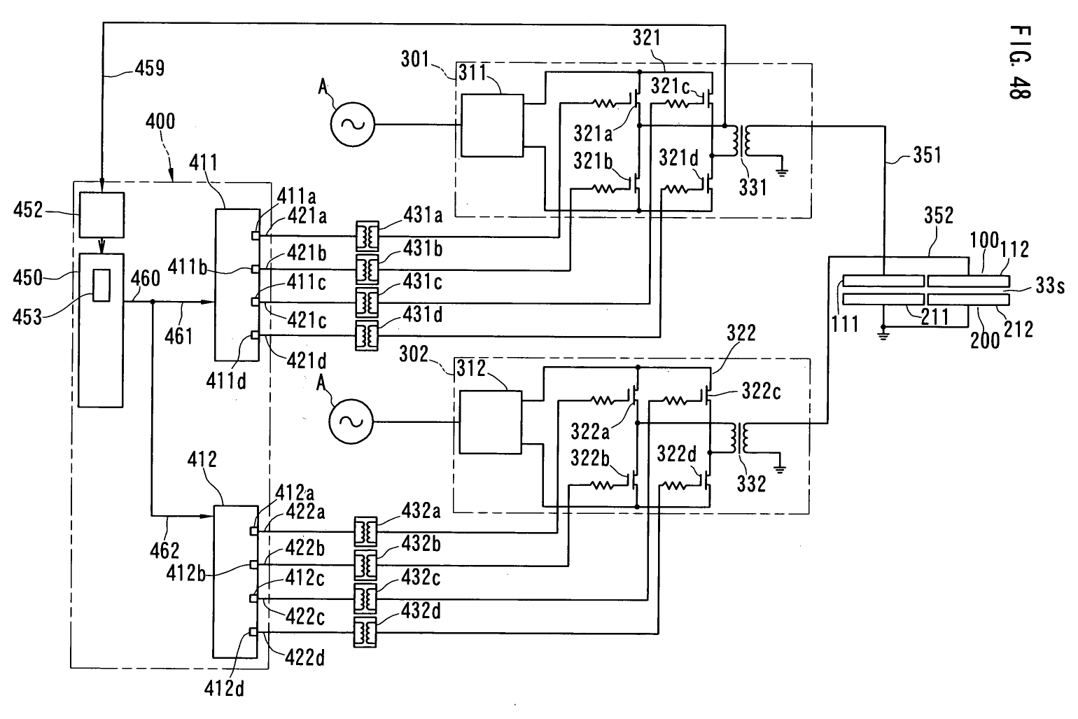

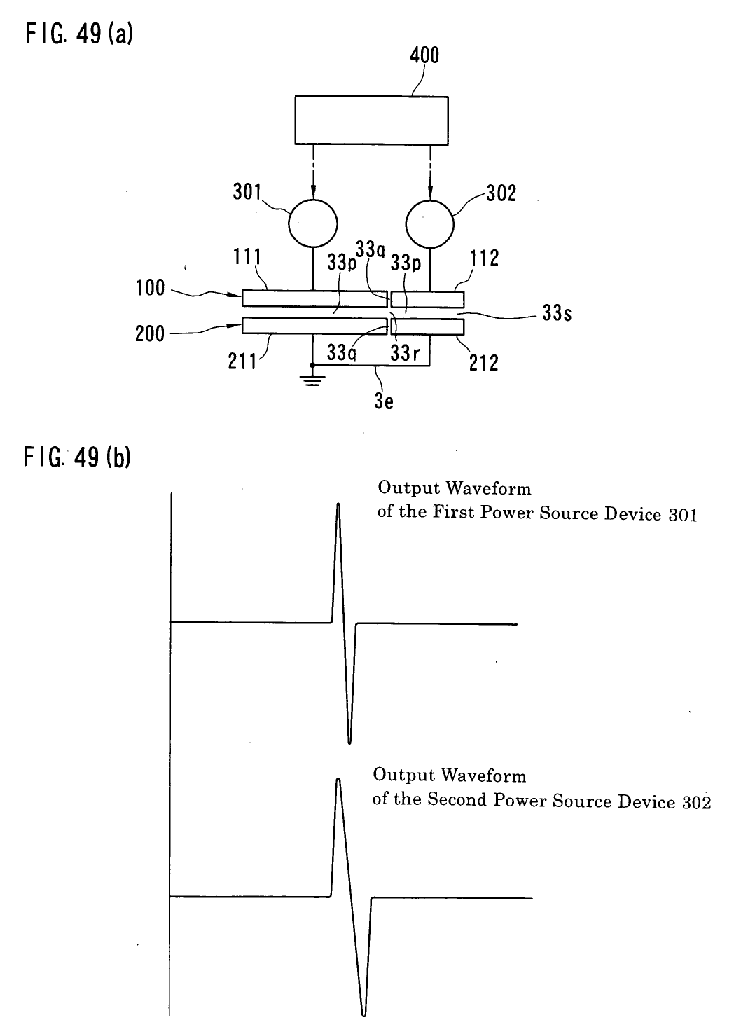

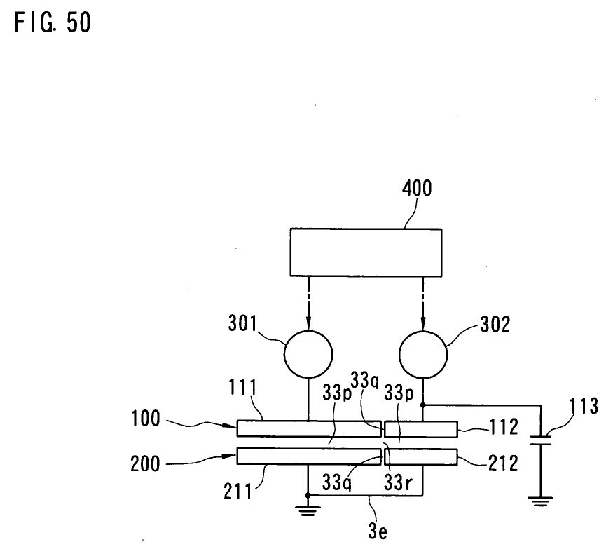

### DESCRIPTION OF REFERENCE NUMERAL

W . . . workpiece
2 . . . processing gas source
3A, 3B, 3C . . . power source
3 . . . common (single) power source
30 . . . discharge processing part
30X . . . electrode unit (electrode structure)
31X . . . first electrode row
31A, 31B, 31C, 31D . . . electrode member
32X . . . second electrode-row
32A, 32B, 32C, 32C . . . electrode member
33s . . . row-to-row gap
33p . . . row-to-row partial gap
33r . . . communication space
33q . . . in-row gap
31d . . . obtuse angle side corner
31e . . . acute angle side corner
32d . . . obtuse angle side corner
32e . . . acute angle side corner
33u . . . intersecting part between the first electrode row and the in-row gap
33v . . . intersecting part between the second electrode row and the row-to-row gap
43 . . . introduction port forming part
43a . . . processing gas introduction port
43b . . . branch port (gas guide) corresponding to a part near the second position of the first row-to-row partial gap
43d . . . branch port (gas guide) corresponding to a part near the second position of the first-row-to-row partial gap
43h . . . row-to-row introduction port (main introduction port)
43i . . . in-row introduction port (auxiliary introduction port)
49 . . . lower plate (jet port forming part)
49a . . . slit-like jet port
49B . . . gas guiding part (gas guide)
49c . . . gas guiding surface
49d . . . upper stage jet port
49E . . . bridge part (blocking part for blocking the end part on the jet port side at the boundary between the adjacent row-to-row partial gaps of the jet port)
49f . . . lower stage jet port
49g . . . upper side space from the porous plate of the jet port
49h . . . row-to-row jet port
49i . . . in-row jet port (jet port of a large opening width, gas guide)
49j . . . diamond-shaped opening (jet port of a large opening width, gas guide)
49k . . . triangular opening (jet port of a large opening width, gas guide)
49m . . . row-to-row jet port
49n . . . inclination in-row jet port
49U . . . upper stage plate part of the lower plate
49L . . . lower stage plate part of the lower plate
51 . . . gas guiding member (gas guide)
51a . . . gas guiding surface
52 . . . gas guiding member (gas guide)
52a . . . gas guiding surface
52b . . . gas return surface
53 . . . gas guiding member (gas guide)
54 . . . gas guiding member (gas guide)
53a, 54a . . . gas guiding surface
60 . . . flow rectification member as the gas guide
62 . . . flow rectification plate arranged near the communication space
70 . . . blocking member (blocking part)
80 . . . gate type space
81 . . . et part (insertion part between the adjacent electrode members)
82 . . . connection part (blocking part)
90 . . . porous plate as the gas guide
90a . . . plurality of apertures
100 . . . electric field applying electrode
200 . . . grounding electrode
301 first power source device
302 . . . second power source device
400 . . . synchronizer
111 . . . first divided electrode member
112 . . . second divided electrode member
211, 212 . . . divided electrode member of the grounding electrode
311 . . . first DC rectifier
321 . . . first inverter
331 first transformer
321a, 321b, 321c, 321d . . . first switching element
312 . . . second DC rectifier
322 . . . second inverter
332 . . . second transformer
322a, 322b, 322c, 322d . . . second switching element
410 . . . common (single) gate signal output part
411 . . . first gate signal output part
412 . . . second gate signal output part
450 . . . common synchronization signal supply part
A . . . commercial use AC power source

1. An electrode structure of a plasma processing apparatus for plasmatizing a processing gas in a discharge space and jetting the plasmatized gas so as to be contacted to a workpiece to be processed, said electrode structure forming said discharge space in said apparatus, said electrode structure comprising:
a first electrode row including a plurality of electrode members each having a length shorter than that of said workpiece and arranged in a side-by-side relation in one direction, said first electrode row as a whole having a length corresponding to that of said workpiece;
a second electrode row including another plurality of electrode members each having a length shorter than that of said workpiece and arranged in a side-by-side relation with each other and in a parallel relation with said first electrode row, said second electrode row as a whole having a length corresponding to that of said workpiece;
one of said electrode members of said first electrode row and one of said electrode members of said second electrode rows, which are arranged in substantially same positions in the side-by-side arranging directions, having opposite polarities and forming a row-to-row partial gap therebetween, said row-to-row partial gap serving as a part of said discharge space; and
a row-to-row gap including said row-to-row partial gap between said first and second electrode rows, said row-to-row gap having a length corresponding to that of said workpiece.

2. An electrode structure of a plasma processing apparatus according to claim 1, wherein said polarities include an electric field applying pole and a grounding pole, only those of said electrode members constituting said electric field applying pole being connected to different power sources, respectively.

3. An electrode structure of a plasma processing apparatus according to claim 1, wherein said polarities include an electric field applying pole and a grounding pole, only those of said electrode members constituting said electric field applying pole being connected to a common power source.

4. An electrode structure of a plasma processing apparatus for plasmatizing a processing gas in a discharge space and jetting the plasmatized gas so as to be contacted to a workpiece to be processed, said electrode structure forming said discharge space in said apparatus, said electrode structure comprising:
a first electrode row including a plurality of electrode members arranged in a side-by-side relation in one direction;
a second electrode row including another plurality of electrode members arranged in a side-by-side relation with each other and in a parallel relation with said first electrode row;
one of said electrode members of said first electrode row and one of said electrode members of said second electrode rows, which are arranged in substantially same positions in the side-by-side arranging directions, having opposite polarities and forming a row-to-row partial gap therebetween, said row-to-row partial gap serving as a part of said discharge space;
a row-to-row gap including said row-to-row partial gap formed between said first and second electrode rows; and
two of said electrode members of each of said electrode rows arranged adjacent to each other in said side-by-side arranging directions being opposite in polarity with respect to each other.

5. An electrode structure of a plasma processing apparatus according to claim 4, wherein an in-row gap is formed between two of said electrode members arranged adjacent to each other in said side-by-side arranging directions in said first electrode row and/or said second electrode row, said in-row gap also forming a part of said discharge space.

6. An electrode structure of a plasma processing apparatus according to claim 5, wherein one of said two electrode members includes a first surface forming said row-to-row gap and a second surface disposed at an angle with respect to said first surface, and the other of said two electrode members includes a third surface generally flush with said first surface and forming said row-to-row gap and a fourth surface placed opposite to said second surface and arranged at an angle with respect to said third surface, said in-row gap being formed between said second surface and said fourth surface.

7. An electrode structure of a plasma processing apparatus according to claim 6, wherein said first surface and second surface form an obtuse angle and said third surface and fourth surface form an acute angle, said in-row gap being in a slantwise relation with said row-to-row gap.

8. An electrode structure of a plasma processing apparatus according to claim 7, wherein corners on the side of the obtuse angle formed between said first surface and second surface are R-chamfered with a relatively large radius of curvature, while corners on the side of the acute angle formed between said third surface and fourth surface are R-chamfered with a relatively small radius of curvature.

9. An electrode structure of a plasma processing apparatus according to claim 7, wherein in said electrode row on the opposite side of said electrode row having said first surface, said electrode member located in the substantially same position as said electrode member having said first surface is arranged astride said first surface and the end face of said third surface.

10. An electrode structure of a plasma processing apparatus according to claim 7, wherein the downstream end of said in-row gap is open in such a manner as to be able to jet a processing gas therefrom and without passing the processing gas through said row-to-row gap.

11. An electrode structure of a plasma processing apparatus for plasmatizing a processing gas in a discharge space and jetting the plasmatized gas so as to be contacted to a workpiece to be processed, said electrode structure forming said discharge space in said apparatus, said electrode structure comprising:
a first electrode row including a plurality of electrode members arranged in a side-by-side relation in one direction;
a second electrode row including another plurality of electrode members arranged in a side-by-side relation with each other and in a parallel relation with said first electrode row;
one of said electrode members of said first electrode row and one of said electrode members of said second electrode rows, which are arranged in substantially same positions in the side-by-side arranging directions, having opposite polarities and forming a row-to-row partial gap therebetween, said row-to-row partial gap serving as a part of said discharge space;
a row-to-row gap including said row-to-row partial gap formed between said first and second electrode rows; and
two of said electrode members of each of said electrode rows arranged adjacent to each other in said side-by-side arranging directions being same in polarity with respect to each other.

12. An electrode structure of a plasma processing apparatus according to claim 11, wherein said polarities include an electric field applying pole and a grounding pole, and an insulating partition wall is interposed between two of said electrode members having said electric field applying pole which are adjacent to each other in said side-by-side arranging directions.

13. A plasma processing apparatus for introducing a processing gas into a discharge space from an introduction port, plasmatizing the gas in said discharge space and jetting the plasmatized gas through a jet port so as to be contacted to a workpiece to be processed, said apparatus comprising:
an electrode structure including a first electrode row consisting of a plurality of electrode members arranged in a side-by-side relation in a direction intersecting with a direction toward said jet port from said introduction port, and another plurality of electrode members arranged in a side-by-side relation with each other and in parallel with said first electrode row; and
one of said electrode members of said first electrode row and one of said electrode members of said second electrode rows, which are arranged at a first position in said side-by-side arranging directions, having opposite polarities and forming a first row-to-row partial gap therebetween, said first row-to-row partial gap serving as a part of said discharge space, and another of said electrode members of said first electrode row and another of said electrode members of said second electrode rows, which are arranged at a second position adjacent to said first position having opposite polarities with each other and forming a second row-to-row partial gap therebetween, said second row-to-row partial gap serving as another part of said discharge space;
said apparatus further comprising a gas guide which guides a processing gas flow passing through a part near said second position in said first row-to-row partial gap to a boundary between said first position and said second position or in a direction toward said second position.

14. A plasma processing apparatus according to claim 13, wherein said first row-to-row partial gap is provided inside said part near said second position with a gas guiding member, as said gas, having a gas guiding surface slanted toward said second position.

15. A plasma processing apparatus according to claim 14, wherein said gas guiding member is provided on said jet port side from said gas guiding surface with a gas return surface slanted in an opposite direction to said gas guiding surface.

16. A plasma processing apparatus according to claim 13, further comprising an introduction port forming part for forming said introduction port, said gas guide being disposed at said introduction port forming part.

17. A plasma processing apparatus according to claim 16, wherein said introduction port of said introduction port forming part includes a branch port leading to said part near said second position of said first row-to-row partial gap, said branch port being disposed toward said second position thereby constituting said gas guide.

18. A plasma processing apparatus according to claim 16, wherein a flow rectification plate, as said gas instruction means, slanted toward said second position is received in said introduction port of said introduction port forming part at a position corresponding to said part near said second position of said first row-to-row partial gap.

19. A plasma processing apparatus according to claim 13, wherein said gas guide includes a blocking part for blocking an end part on said introduction port side located at the boundary between said first row-to-row partial gap and said second row-to-row partial gap and opening the area on the jet port side therefrom.

20. A plasma processing apparatus according to claim 19, further comprising an introduction port forming part for forming said introduction port, said introduction port of said introduction port forming part having a slit-like configuration extending in said side-by-side arranging directions and disposed astride said first row-to-row part gas and said second row-to-row partial gap, said blocking part being received in said introduction port at a position corresponding to said boundary between said first row-to-row partial gap and said second row-to-row partial gap.

21. A plasma processing apparatus according to claim 19, wherein said electrode structure comprises a spacer having a pair of interposing parts and a connection part for connecting said interposing parts, one of said interposing parts being sandwiched between said electrode member located at said first position and said electrode member located at said second position in said first electrode row, the other of said interposing parts being sandwiched between said electrode member located at said first position and said electrode member located at said second position in said second electrode row, said connection part being arranged close to the end part on said introduction port side of said boundary, thereby being provided as said blocking part.

22. A plasma processing apparatus according to claim 13, further comprising a jet port forming part for forming said jet port,
said gas guide being disposed at said jet port forming part and introducing a processing gas coming from said part near said second position of said first row-to-row partial gap toward said second position.

23. A plasma processing apparatus according to claim 22, wherein said gas guide includes a gas guiding surface inclined in a second direction and arranged at a position corresponding to said part near said second position of said first row-to-row partial gap in said jet port of said jet port forming part.

24. A plasma processing apparatus according to claim 22, wherein said gas guide is arranged at a position corresponding to the boundary between said first row-to-row partial gap and said second row-to-row partial gap in said jet port of said jet port forming part in such a manner as to be close to said electrode structure side, and said gas guide includes a blocking part for blocking the end part on said jet port side of said boundary.

25. A plasma processing apparatus according to claim 22, wherein said jet port forming part includes a porous plate, a processing gas coming from said first row-to-row partial gap being dispersed and thus, diffused also toward said second position and jetted out, thereby providing said porous plate as said gas guide.

26. A plasma processing apparatus according to claim 22, wherein a part of said jet port of said jet port forming part corresponding to said boundary between said first row-to-row partial gap and said second row-to-row partial gap is larger in opening width than another part of said jet port of said jet port forming part corresponding to said first row-to-row partial gap, and said former part having the large opening width is provided as said gas guide.

27. A plasma processing apparatus for introducing a processing gas into a discharge space from an introduction port, plasmatizing the gas in said discharge space and jetting the plasmatized gas through a jet port so as to be contact to a workpiece to be processed, said apparatus comprising:
an electrode structure including a first electrode row consisting of a plurality of electrode members arranged in a side-by-side relation in a direction intersecting with a direction toward said jet port from said introduction port, and another plurality of electrode members arranged in a side-by-side relation with each other and in parallel with said first electrode row; and
one of said electrode members of said first electrode row and one of said electrode members of said second electrode rows, which are arranged at a first position in said side-by-side arranging directions, having opposite polarities and forming a first row-to-row partial gap therebetween, said first row-to-row partial gap serving as a part of said discharge space, and another of said electrode members of said first electrode row and another of said electrode members of said second electrode rows, which are arranged at a second position adjacent to said first position having opposite polarities with each other and forming a second row-to-row partial gap therebetween, said second row-to-row partial gap serving as another part of said discharge space, said electrode member which is arranged at the first position in said first electrode row and said electrode member which is arranged at the second position in said first electrode row having opposite polarities each other and forming an in-row gap therebetween;
said apparatus further comprising an introduction port forming part for forming said introduction port; and
said introduction port of said introduction port forming part including a row-to-row introduction port disposed astride said first row-to-row partial gap and said second row-to-row partial gap and an in-row introduction port directly connected to said in-row gap.

28. A plasma processing apparatus comprising an electric field applying electrode and a grounding electrode which are placed opposite to each other and form a processing gas path therebetween, a plurality of power source devices for applying an electric field for plasmatizing said processing gas between said electrodes, and a synchronizer which synchronizes said power source devices.

29. A plasma processing apparatus according to claim 28, wherein said plurality of power source devices each include a rectification path for rectifying a commercial-use AC voltage to a DC voltage, and an inverter for switching the DC voltage after rectification to an AC voltage by a switching element, said synchronizer controlling said inverters for said power source devices such that said inverters are synchronized in switching action with each other.

30. A plasma processing apparatus according to claim 29, wherein said synchronizer includes a common gate signal output part for said inverters of said power source devices, a gate signal outputted from said gate signal output part being inputted in a gate of said switching element of each of said inverters in parallel.

31. A plasma processing apparatus according to claim 29, wherein said synchronizer includes a plurality of gate signal output parts which are provided to said inverter of each power source device and a common synchronization signal supply part for said gate signal output parts, a synchronization signal outputted from said synchronization signal supply part being inputted into each of said gate signal output parts in parallel so that in response to input of said synchronization signal, said gate signal output parts each input a gate signal into said gate of said switching element of the corresponding inverter.

32. A plasma processing apparatus comprising:
an electric field applying electrode including a first and a second divided electrode member;
a grounding electrode for forming a processing gas path between said first and second electric field applying electrodes;
a first power source device for applying an electric field for plasmatizing said processing gas between said first divided electrode member and said grounding electrode;
a second power source device for applying an electric field for plasmatizing said processing gas between said second divided electrode member and said grounding electrode; and
a synchronizer which synchronizes said first and second power source devices.

33. A plasma processing apparatus according to claim 32, wherein electrostatic capacity between said first divided electrode member and said grounding electrode is larger than that between said second divided electrode member and said grounding electrode, and
said second electrode device is longer in rising/falling time of applied voltage than said first power source device.

34. A plasma processing apparatus according to claim 32, wherein electrostatic capacity between said first divided electrode member and said grounding electrode is larger than that between said second divided electrode member and said grounding electrode, and
said second divided electrode member is connected with a condenser in parallel.
